(19) United States
(12) Patent Application Publication
(10) Pub. No.: US 2026/0114101 A1
(43) Pub. Date: Apr. 23, 2026

(54) DISPLAY DEVICE AND ELECTRONIC DEVICE, AND METHOD OF MANUFACTURING DISPLAY DEVICE

(71) Applicant: Samsung Display Co., LTD., Yongin-si (KR)

(72) Inventors: Woo Lim JEONG, Yongin-si (KR); Jin Hyuk JANG, Yongin-si (KR); Jun Youn KIM, Yongin-si (KR); Kwan Jae LEE, Yongin-si (KR); Dong Eon LEE, Yongin-si (KR); Sang Tae LEE, Yongin-si (KR)

(73) Assignee: Samsung Display Co., LTD., Yongin-si (KR)

(21) Appl. No.: 19/214,552

(22) Filed: May 21, 2025

(30) Foreign Application Priority Data
Oct. 17, 2024 (KR) 10-2024-0142129

(51) Int. Cl. H10H 29/851; H10H 29/01; H10H 29/856

(52) U.S. Cl. CPC H10H 29/8514; H10H 29/012; H10H 29/0361; H10H 29/8512; H10H 29/856

(57) ABSTRACT

Provided is a display device including a backplane substrate, a light emitting element layer including first electrodes disposed on the backplane substrate, light emitting elements disposed on the first electrodes, and a first oxide layer covering the light emitting elements, and a light conversion layer disposed on the light emitting element layer, the light conversion layer including color conversion layers overlapping the light emitting elements, and a second oxide layer covering lower surfaces of the color conversion layers, wherein the first oxide layer and the second oxide layer are bonded together.

### CROSS-REFERENCE TO RELATED APPLICATION(S)

This application claims priority to and benefits of Korean Patent Application No. 10-2024-0142129 under 35 U.S.C. § 119, filed on Oct. 17, 2024, in the Korean Intellectual Property Office, the entire contents of which are incorporated herein by reference.

### BACKGROUND

### 1. Technical Field

Embodiments of the disclosure relate to a display device and an electronic device, and a method of manufacturing the display device.

### 2. Description of the Related Art

With the advance of information-oriented society, more and more demands are placed on display devices for displaying images in various ways. Along with this trend, various types of display devices including a light emitting display device are being developed. The light emitting display device includes pixels each including light emitting elements.

### SUMMARY

Aspects of the disclosure provide a display device and an electronic device, and a method of manufacturing the display device that may simplify the manufacturing process.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including, a backplane substrate, a light emitting element layer including first electrodes disposed on the backplane substrate, light emitting elements disposed on the first electrodes, and a first oxide layer covering the light emitting elements, and a light conversion layer disposed on the light emitting element layer, the light conversion layer including color conversion layers overlapping the light emitting elements, and a second oxide layer covering lower surfaces of the color conversion layers, wherein the first oxide layer and the second oxide layer are bonded together.

In an embodiment, the light emitting elements may emit ultraviolet or blue light.

In an embodiment, the color conversion layers may include a first color conversion layer, a second color conversion layer, and a third color conversion layer converting light emitted from the light emitting elements into light of a first color, light of a second color, and light of a third color, respectively.

In an embodiment, the light of the first color, the light of the second color and the light of the third color may be red light, green light and blue light, respectively.

In an embodiment, the first color conversion layer, the second color conversion layer, and the third color conversion layer may include a nitride-based semiconductor material and have a multiple quantum well structure.

In an embodiment, quantum well layers of each of the first color conversion layer, the second color conversion layer, and the third color conversion layer may include indium, and an indium content of the quantum well layers of the first color conversion layer, an indium content of the quantum well layers of the second color conversion layer, and an indium content of the quantum well layers of the third color conversion layer may be different from each other.

In an embodiment, the light emitting element layer may include first reflective layers disposed between the first electrodes and the light emitting elements and covering a lower surface of each of the light emitting elements, and second reflective layers disposed on the light emitting elements and covering an upper surface of each of the light emitting elements.

In an embodiment, a reflectivity of the first reflective layers may be higher than a reflectivity of the second reflective layers.

In an embodiment, the first reflective layers may include a conductive material.

In an embodiment, each of the second reflective layers may include first layers and second layers alternately stacked to form a distributed Bragg reflector.

In an embodiment, a second layer including oxide may be disposed in an uppermost portion of each of the second reflective layers.

In an embodiment, an upper surface of the first oxide layer and upper surfaces of the second reflective layers are coplanar with each other to expose upper surfaces of the second reflective layers, and the second oxide layer may be bonded to the first oxide layer and the second reflective layers.

In an embodiment, the first oxide layer may cover upper surfaces of the second reflective layers.

In an embodiment, the light emitting element layer may further include second electrodes disposed between the light emitting elements and the second reflective layers.

In an embodiment, a distance between the first reflective layers and the second reflective layers may be N, where N is a natural number, times an emission wavelength of the light emitting elements., In an embodiment, the light conversion layer may further include third reflective layers surrounding side surfaces of the color conversion layers.

In an embodiment, the display device may further include color filters and a lens disposed on the light conversion layer and covering the color conversion layers.

In an embodiment, the first oxide layer and the second oxide layer may include SiO₂ or Al₂O₃.

According to an aspect of the disclosure, there is provided a method of manufacturing a display device, including, forming a display substrate including a backplane substrate and a light emitting element layer, and the light emitting element layer including a first oxide layer covering light emitting elements of the light emitting element layer, forming a light conversion layer including color conversion layers and a second oxide layer covering the color conversion layers, and disposing the display substrate and the light conversion layer to face each other, and bonding the first oxide layer and the second oxide layer to bond the display substrate and the light conversion layer.

In an embodiment, the forming of the light conversion layer may include, sequentially forming a first color conversion layer, a second color conversion layer, and a third color conversion layer by epitaxial growth on different regions of a manufacturing substrate, forming a reflective layer on a side surface of each of the first color conversion layer, the second color conversion layer, and the third color conversion layer, and forming the second oxide layer to cover the first color conversion layer, the second color conversion layer, the third color conversion layer, and the reflective layer.

According to an aspect of the disclosure, there is provided an electronic device including a display module including a display panel, and a processor which transmits an image data signal to the display module. The display panel may include a backplane substrate, a light emitting element layer including first electrodes disposed on the backplane substrate, light emitting elements disposed on the first electrodes, and a first oxide layer covering the light emitting elements, and a light conversion layer disposed on the light emitting element layer, the light conversion layer including color conversion layers overlapping the light emitting elements, and a second oxide layer covering lower surfaces of the color conversion layers, and the first oxide layer and the second oxide layer may be bonded together.

In the display device and the electronic device, and the method of manufacturing the display device according to embodiments, the structure of the display device or the electronic device may be simplified, and manufacturing efficiency of the display device or the electronic device may be improved.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic cross-sectional view illustrating a display device according to an embodiment;

FIG. 3 is a schematic cross-sectional view illustrating a display device according to an embodiment;

FIG. 4 is a schematic cross-sectional view illustrating a display device according to an embodiment;

FIG. 5 is a schematic cross-sectional view illustrating a display device according to an embodiment;

FIG. 6 is a schematic cross-sectional view showing a light emitting layer according to an embodiment;

FIG. 7 is a schematic diagram illustrating a resonant structure according to an embodiment;

FIG. 8 is a schematic cross-sectional view illustrating a color conversion layer according to an embodiment;

FIG. 9 is a schematic flowchart illustrating a method of manufacturing a display device according to an embodiment;

FIG. 10 is a schematic cross-sectional view showing a display substrate according to an embodiment;

FIGS. 11 to 16 are schematic cross-sectional views sequentially illustrating a method of forming a light conversion layer according to an embodiment;

FIGS. 17 and 18 are schematic cross-sectional views sequentially illustrating a method of bonding (or coupling) a display substrate to a light conversion layer according to an embodiment;

FIG. 19 is a schematic cross-sectional view illustrating a display device manufactured according to an embodiment;

FIG. 20 is a schematic diagram illustrating a smart watch including a display device according to an embodiment;

FIGS. 21 and 22 schematically illustrate a head mounted display including a display device according to an embodiment;

FIG. 23 schematically illustrates a head mounted display including a display device according to an embodiment;

FIG. 24 is a schematic diagram illustrating a dashboard of an automobile and a center fascia including display devices according to an embodiment; and

FIG. 25 is a schematic diagram illustrating a transparent display device including a display device according to an embodiment.

FIG. 26 is a schematic block diagram of an electronic device according to an embodiment of the disclosure.

### DETAILED DESCRIPTION OF THE EMBODIMENTS

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on another element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

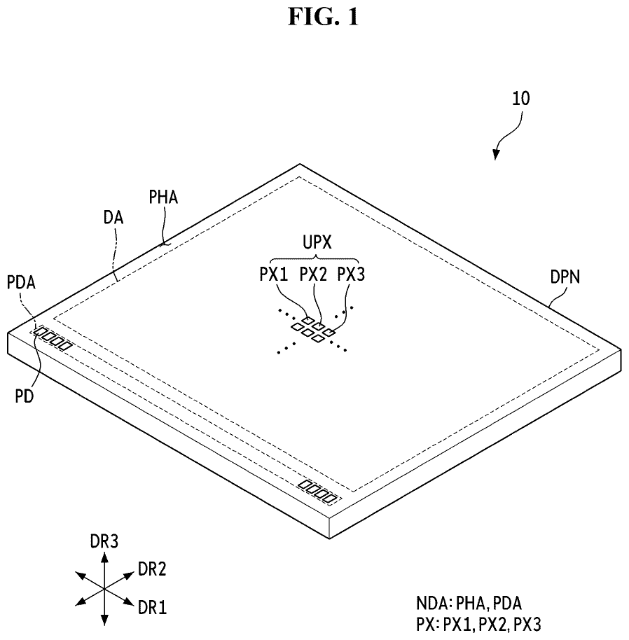

FIG. 1 is a schematic perspective view illustrating a display device according to an embodiment.

Referring to FIG. 1, a display device 10 is a device for displaying a moving image or a still image, and may be used as a display screen for various electronic devices. For example, the display device 10 may be used as a display screen for various electronic devices such as televisions, laptop computers, monitors, billboards and the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs). The display device 10 may be applied to other electronic devices such as a virtual reality (VR) device, an augmented reality (AR) device, or the like. For example, the display device 10 may be included in at least one of the electronic devices exemplified above, or may be included in electronic devices of other types.

The display device 10 may be a light emitting display device including light emitting elements. For example, the display device 10 may be an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro or nano light emitting diode (micro LED or nano LED).

Hereinafter, embodiments in which the display device 10 is a light emitting display device including a micro or nano light emitting diode will be described. However, the type or size of the light emitting element according to embodiments is not limited thereto.

The display device 10 may include a display panel DPN including a display area DA and a non-display area NDA. The display panel DPN may have a quadrilateral planar shape, but is not limited thereto. For example, the display panel DPN may have a polygonal shape other than a quadrilateral shape, a circular shape, an elliptical shape, or an irregular shape in a plan view. In FIG. 1, a first direction DR1, a second direction DR2, and a third direction DR3 are indicated. The first direction DR1, the second direction DR2, and the third direction DR3 may be the horizontal direction, the vertical direction, and the thickness direction of the display panel DPN, respectively.

The display device 10 may include pixels PX disposed in the display area DA. An image may be displayed in the display area DA by the pixels PX. For example, the pixels PX and wires (or some of the wires) electrically connected to the pixels PX may be disposed in the display area DA. In describing embodiments, the term “connect” may include electrical connection and/or physical connection. Although FIG. 1 illustrates an embodiment in which the planar shape of the display area DA is quadrilateral, the shape of the display area DA is not limited thereto.

The pixels PX may have a quadrilateral planar shape such as a rectangular shape or a rhombic shape, but the disclosure is not limited thereto. For example, the pixels PX may have another polygonal shape (e.g., a hexagonal shape or diamond shape), a circular shape, an elliptical shape, or other planar shapes.

The pixels PX may be electrically connected to a driving circuit and a power supply unit through wires and/or pads PD formed in the display panel DPN to receive driving signals and driving voltages. For example, the pixels PX may receive scan signals (or clock signals), data signals (or digital data), a first driving voltage (e.g., high-potential pixel voltage or anode voltage), and a second driving voltage (e.g., low-potential pixel voltage or cathode voltage). The pixels PX may emit light in response to the driving signals and the driving voltages.

At least a part of the driving circuit that supplies the driving signals to the pixels PX may be formed in the display panel DPN, or may be disposed on the non-display area NDA of the display panel DPN. In another embodiment, the driving circuit may be disposed outside the display panel DPN and electrically connected to multiple pads PD disposed in the pad area PDA. The power supply unit that supplies the driving voltages to the pixels PX may be disposed outside the display panel DPN (for example, circuit board electrically connected to the display panel DPN) and electrically connected to multiple pads PD disposed in the pad area PDA. However, the positions of the driving circuit and the power supply unit, or the connection structure of each of the driving circuit and the power supply unit and the pixels PX may vary according to embodiments.

The pixels PX may include first pixels PX1 (e.g., first color sub-pixels) that emit light of a first color, second pixels PX2 (e.g., second color sub-pixels) that emit light of a second color, and third pixels PX3 (e.g., third color sub-pixels) that emit light of a third color. The first color may be red, the second color may be green, and the third color may be blue, but they are not limited thereto. At least one first pixel PX1, at least one second pixel PX2, and at least one third pixel PX3 adjacent to each other may each constitute a unit pixel UPX. In each unit pixel UPX, light of the first color, light of the second color, or light of the third color may be emitted alone, or a mixture of at least two of light of the first color, light of the second color, or light of the third color may be emitted. Accordingly, the unit pixel UPX may emit light of various colors. The number, type, and/or arrangement structure of the pixels PX constituting the unit pixel UPX may vary depending on the embodiments.

Each pixel PX may include at least one light emitting element. Each light emitting element may have a circular shape, an elliptical shape, a quadrilateral shape, a polygonal shape (e.g., a hexagonal shape or a rhombic shape) other than a quadrilateral shape, or other planar shapes. For example, the planar shape of the light emitting elements may be variously changed according to embodiments.

The first pixels PX1, the second pixels PX2, and the third pixels PX3 may include the light emitting elements that emit light of the same color or wavelength, and color conversion layers and/or color filters may be disposed in the emission areas of the first pixels PX1, the second pixels PX2, and/or the third pixels PX3 to convert or control the color of light emitted from the light emitting elements disposed in each of the pixels PX. In another embodiment, the pixels PX may include the light emitting elements that emit light of different colors. For example, the first pixels PX1, the second pixels PX2, and the third pixels PX3 may include the light emitting elements that emit light of the first color, light of the second color, and light of the third color, respectively.

Each of the pixels PX may further include a pixel circuit electrically connected to the light emitting element. A first driving voltage and driving signals for the pixels PX may be applied to the pixel circuit of each pixel PX, and a second driving voltage may be applied to the light emitting elements through second electrodes (or a common electrode) electrically connected to the light emitting elements of the pixels PX. In describing the following embodiments, the second driving voltage applied to the light emitting elements may also be referred to as “common voltage.”

The non-display area NDA may be an area where an image is not displayed. The non-display area NDA may be disposed around the display area DA. In an example, the non-display area NDA may be disposed at the edge of the display panel DPN to surround the display area DA.

The non-display area NDA may include a pad area PDA and a peripheral area PHA. Wires (or portions of the wires) electrically connected to the pixels PX, and pads PD may be disposed in the non-display area NDA.

The pads PD may be disposed in the pad area PDA. The pads PD may be electrically connected to a circuit board (not shown) through a conductive ball, a wire, or another conductive connection member. The pads PD may be electrically connected to the pixels PX. Through the pads PD, driving signals and driving voltages for driving the display panel DPN may be supplied from the circuit board to the display device 10.

The pad area PDA may be disposed at one end (e.g., lower end) of the display panel DPN. The pad area PDA may include the pads PD to be electrically connected to an external circuit board. The pads PD may be electrically connected to the pixels PX through respective connection lines in the display panel DPN. In case that a driving circuit including at least one of a gate driver, a data driver, or a timing controller is disposed in the display panel DPN and/or on the non-display area NDA, at least some of the pads PD may be electrically connected to the driving circuit, and may transmit the driving signals and the driving voltages of the driving circuit.

The peripheral area PHA may be the remaining area excluding the pad area PDA within the non-display area NDA. The peripheral area PHA may surround the display area DA. Wires electrically connected to the pixels PX and the pads PD may pass through the peripheral area PHA.

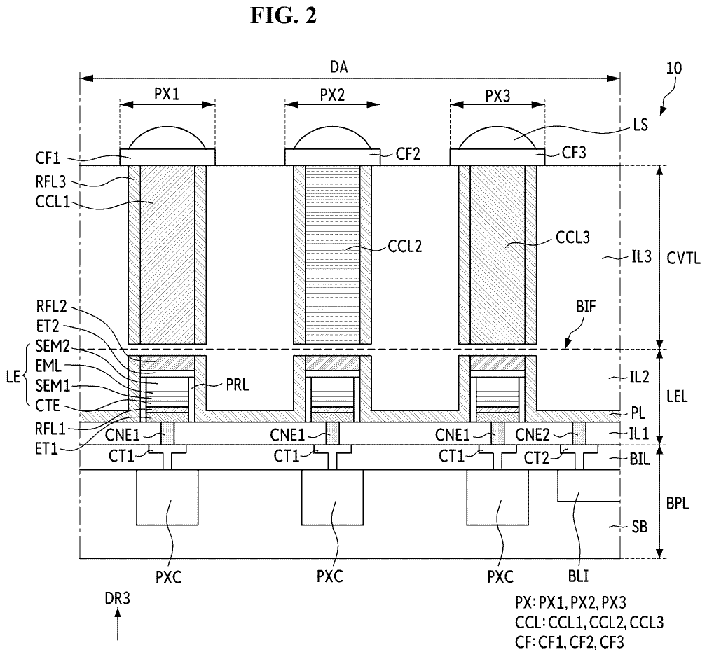

FIG. 2 is a schematic cross-sectional view illustrating a display device according to an embodiment. For example, FIG. 2 illustrates a portion of the display device 10 corresponding to a portion of the display area DA of FIG. 1, and shows a schematic cross-section of the first pixel PX1, the second pixel PX2, and the third pixel PX3, which form one unit pixel UPX among the pixels PX of the display area DA. The first pixel PX1, the second pixel PX2, and the third pixel PX3 may emit light of the first color, light of the second color, and light of the third color, respectively.

Referring to FIGS. 1 and 2, the display device 10 may include a backplane substrate BPL, and a light emitting element layer LEL disposed on the backplane substrate BPL, and a light conversion layer CVTL disposed on the light emitting element layer LEL. The backplane substrate BPL may also be referred to as “lower substrate” or “backplane layer.” The display device 10 may further include an optical filter for increasing the color purity of the pixels PX and an optical structure for increasing the light emission efficiency of the pixels PX. For example, a lens LS and color filters CF covering color conversion layers CCL and light emitting elements LE of the pixels PX may be disposed on the light conversion layer CVTL. The lens LS may be disposed in the display panel DPN in the form of a lens array (e.g., a microlens array) having a size and arrangement corresponding to the pixels PX.

FIG. 2 shows the display device 10 with a light emitting diode-on-silicon (LEDoS) structure in which light emitting diodes are disposed as the light emitting elements LE on the backplane substrate BPL (e.g., a backplane substrate formed as a semiconductor circuit board) formed by a semiconductor process using a silicon wafer. However, the embodiments are not limited thereto. For example, the backplane substrate BPL may be a backplane substrate of a different type or structure, e.g., a thin film transistor substrate in which a thin film transistor is formed on a base substrate such as a glass substrate or a polymer film. The embodiments may be applied to display devices of different types and/or structures, or may be applied to devices of different types and/or structures, such as lighting devices.

The backplane substrate BPL may include a base substrate SB, pixel circuits PXC of the pixels PX, the pads PD of FIG. 1, and the like. The base substrate SB and the backplane substrate BPL including the base substrate may include the display area DA and the non-display area NDA of FIG. 1. The pixel circuits PXC may be disposed in the display area DA, and the pads PD may be disposed in the non-display area NDA.

The backplane substrate BPL may further include wires electrically connected to the pixels PX and the pads PD. For example, the backplane substrate BPL may include signal lines (e.g., signal lines electrically connected between the pads PD or a driving circuit and the pixels PX to transmit scan signals (or clock signals) and data signals (or digital data) to the pixels PX) and power lines (e.g., power lines for transmitting the first driving voltage and the second driving voltage to the pixels PX) electrically connected to the pixels PX.

A first power line for transmitting the first driving voltage may be electrically connected between at least one pad PD disposed in the pad area PDA and the pixel circuits PXC disposed in the display area DA, and may be formed in the backplane substrate BPL. The first power line may transmit the first driving voltage applied from the at least one pad PD to the pixel circuits PXC.

A second power line for transmitting the second driving voltage, e.g., the common voltage may include a backplane power line BLI electrically connected to at least one other pad PD disposed in the pad area PDA and formed in the backplane substrate BPL, a power line PL of the light emitting element layer LEL electrically connected between the backplane power line BLI and second electrodes ET2 of the pixels PX, and a second contact terminal CT2 and a second connection electrode CNE2 electrically connected between the power line PL and the backplane power line BLI.

The backplane power line BLI may be formed in the display area DA and the non-display area NDA, and may be electrically connected to the power line PL formed in the light emitting element layer LEL in the display area DA and to at least one pad PD in the non-display area NDA. In another embodiment, the backplane power line BLI may be formed in the non-display area NDA, and the power line PL of the light emitting element layer LEL may extend from the display area DA to the non-display area NDA and be electrically connected to the backplane power line BLI in the non-display area NDA. The connection structure between the second electrodes ET2 of the pixels PX and the backplane power line BLI and/or the pad PD may vary depending on embodiments. FIG. 2 illustrate an embodiment in which the power line PL of the light emitting element layer LEL is electrically connected to the backplane power line BLI in the display area DA.

The backplane substrate BPL may further include first contact terminals CT1 disposed on the pixel circuits PXC, and the second contact terminal CT2 and a lower insulating layer BIL (or a passivation layer) on the backplane power line BLI. Although FIG. 2 illustrates one lower insulating layer BIL disposed on the pixel circuits PXC and surrounding the first contact terminals CT1 and the second contact terminal CT2, the embodiments are not limited thereto. For example, multiple insulating layers and multiple conductive layers may be disposed on the base substrate SB where the pixel circuits PXC are formed. The pixel circuits PXC, the first contact terminals CT1, the second contact terminal CT2, and backplane wires including the backplane power line BLI may be disposed or formed on the base substrate SB. The pads PD of FIG. 1 may be disposed on the backplane substrate BPL. The pads PD may be electrically connected to the backplane wires.

The backplane substrate BPL may be formed through a semiconductor process using a silicon wafer. For example, the base substrate SB may be a silicon wafer. The base substrate SB may be made of monocrystalline silicon.

The pixel circuits PXC may be disposed in the backplane substrate BPL to correspond to the respective pixel areas where the respective pixels PX are disposed. Each of the pixel circuits PXC may include a complementary metal oxide semiconductor (CMOS) circuit formed using a semiconductor process. For example, each of the pixel circuits PXC may include at least one transistor and at least one capacitor formed through a semiconductor process.

Each pixel PX may include the pixel circuit PXC and at least one light emitting element LE electrically connected to the pixel circuit PXC. The pixel circuit PXC may control a driving current flowing through the light emitting element LE of each pixel PX in response to the driving signals inputted from the outside.

The first contact terminals CT1 and the lower insulating layer BIL may be disposed on the pixel circuits PXC. The first contact terminals CT1 (or portions of the pixel circuits PXC) may be exposed on the top surface (or upper surface) of the backplane substrate BPL and surrounded by the lower insulating layer BIL. The first contact terminals CT1 may be in contact with and/or electrically connected to first electrodes ET1 (e.g., first pixel electrodes or anode electrodes) of the pixels PX through the exposed portions.

Although FIG. 2 illustrates the first contact terminals CT1 and the pixel circuits PXC in separate configurations, the embodiments are not limited thereto. For example, the first contact terminals CT1 may be portions of the respective pixel circuits PXC. In an example, the first contact terminals CT1 may be exposed electrodes (or wires) protruding from the top surfaces (or upper surfaces) of the respective pixel circuits PXC.

The first contact terminal CT1 of each pixel PX may electrically connect the pixel circuit PXC of the corresponding pixel PX to the first electrode ET1 thereof. The first contact terminal CT may receive the first driving voltage from each pixel circuit PXC. The first contact terminal CT1 of each pixel PX may be electrically connected to the light emitting element LE of the corresponding pixel PX via a first connection electrode CNE1 and the first electrode ET1 of the corresponding pixel PX.

The second contact terminal CT2 may electrically connect the backplane power line BLI to the power line PL of the light emitting element layer LEL. The second contact terminal CT2 may receive the second driving voltage, e.g., the common voltage, from the backplane power line BLI. The second contact terminal CT2 may be electrically connected to the power line PL of the light emitting element layer LEL via the second connection electrode CNE2.

The first contact terminals CT1 and the second contact terminal CT2 may include a conductive material. For example, the first contact terminals CT1 and the second contact terminal CT2 may include, but not limited to, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof.

The lower insulating layer BIL may surround the first contact terminals CT1 and the second contact terminal CT2. In an example, the lower insulating layer BIL may be disposed on the base substrate SB, the pixel circuits PXC, and the backplane power line BLI, and may surround the side surfaces of the first contact terminals CT1 and the second contact terminal CT2. FIG. 2 illustrates an embodiment in which the lower insulating layer BIL entirely surrounds the side surfaces of the first contact terminals CT1 and the second contact terminal CT2, but the embodiments are not limited thereto. For example, the lower insulating layer BIL may be formed at a height lower than the first contact terminals CT1 and the second contact terminal CT2, and the top surfaces (or upper surfaces) of the first contact terminals CT1 and the second contact terminal CT2 may protrude higher than the top surface (or upper surface) of the lower insulating layer BIL.

The lower insulating layer BIL may include openings (or contact holes) corresponding to the first contact terminals CT1 and the second contact terminal CT2. In an example, the lower insulating layer BIL may be opened to expose the top surfaces (or upper surfaces) of the first contact terminals CT1 and the top surface (or upper surface) of the second contact terminal CT2.

The lower insulating layer BIL may include at least one insulating material and may have a single-layer or multilayer structure. The lower insulating layer BIL may include at least one inorganic insulating layer including an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or another inorganic insulating material).

The light emitting element layer LEL may include the light emitting elements LE, electrodes and/or wire electrically connected to the light emitting elements LE, and insulating layers and reflective layers disposed around the light emitting elements LE.

The electrodes of the light emitting element layer LEL may include the first electrodes ET1 and the second electrodes ET2 electrically connected to both ends of the respective light emitting elements LE, the first connection electrodes CNE1 respectively electrically connected between the first electrodes ET1 and the first contact terminals CT1, and the second connection electrode CNE2 electrically connected between the power line PL of the light emitting element layer LEL and the second contact terminal CT2.

The wire of the light emitting element layer LEL may include the power line PL electrically connected between the second electrodes ET2 and the second connection electrode CNE2. The power line PL may be a common layer to which the second electrodes ET2 of the pixels PX are connected in common, and may include openings corresponding to the light emitting elements LE in a plan view. In an example, the power line PL may have a mesh shape in a plan view.

FIG. 2 illustrates the display device 10 having a structure in which the first electrodes ET1 are disposed on a first insulating layer IL1 covering the backplane substrate BPL and the light emitting elements LE are bonded (or coupled) to the backplane substrate BPL through the first electrodes ET1, but the structure of the display device 10 is not limited thereto. For example, the light emitting elements LE may be appropriately disposed on the backplane substrate BPL using other connection electrodes or wires instead of a bonding method.

The insulating layers of the light emitting element layer LEL may include a first insulating layer IL1 and a second insulating layer IL2 sequentially disposed on the backplane substrate BPL. The insulating layers of the light emitting element layer LEL may further include a protective film PRL surrounding the side surfaces of the light emitting elements LE and the first electrodes ET1.

Each of the insulating layers of the light emitting element layer LEL may be constituted with a single layer or multiple layers including an insulating material. Each of the insulating layers of the light emitting element layer LEL may include an inorganic insulating layer including an inorganic insulating material (e.g., silicon oxide (SiOₓ), silicon nitride (SiNₓ), silicon oxynitride (SiOₓN_{y}), silicon oxycarbide (SiOₓC_{y}), aluminum oxide (AlₓO_{y}), aluminum nitride (AlNₓ), zirconium oxide (ZrOₓ), hafnium oxide (HfOₓ), titanium oxide (TiOₓ), or other inorganic insulating materials), but is not limited thereto.

The reflective layers of the light emitting element layer LEL may include a first reflective layer RFL1 and a second reflective layer RFL2 covering both ends of each of the light emitting elements LE. For example, the first reflective layer RFL1 and the second reflective layer RFL2 may be disposed on the bottom surface (or lower surface) and the top surface (or upper surface) of each of the light emitting elements LE, respectively.

The first connection electrodes CNE1, the second connection electrode CNE2, and the first insulating layer IL1 may be disposed on the backplane substrate BPL. For example, the first connection electrodes CNE1 may be disposed on the respective first contact terminals CT1 and the second connection electrode CNE2 may be disposed on the second contact terminal CT2. The first connection electrodes CNE1 and the second connection electrode CNE2 may penetrate the first insulating layer IL1.

The first connection electrodes CNE1 may be disposed between the backplane substrate BPL and the first electrodes ET1 to connect the backplane substrate BPL to the first electrodes ET1. For example, the first connection electrode CNE1 of each pixel PX may be electrically connected between the first contact terminal CT1 and the first electrode ET1 of the corresponding pixel PX. Although FIG. 2 illustrates the first connection electrodes CNE1 and the first electrodes ET1 as separate elements, the embodiments are not limited thereto. For example, the first connection electrodes CNE1 may be parts of the respective first electrodes ET1.

The second connection electrode CNE2 may be disposed between the backplane substrate BPL and the power line PL to connect the backplane substrate BPL to the power line PL. For example, the second connection electrode CNE2 may be electrically connected between the second contact terminal CT2 electrically connected to the backplane power line BLI and the power line PL. Although FIG. 2 illustrates the second connection electrode CNE2 and the power line PL as separate elements, the embodiments are not limited thereto. For example, the second connection electrode CNE2 may be considered as a part of the power line PL.

The first connection electrodes CNE1 and the second connection electrode CNE2 may include a conductive material. For example, the first connection electrodes CNE1 and the second connection electrode CNE2 may include at least one of gold (Au), copper (Cu), tin (Sn), titanium (Ti), aluminum (Al), silver (Ag), or other metals.

The first insulating layer IL1 may be disposed on the backplane substrate BPL. The first insulating layer IL1 may include openings corresponding to the first connection electrodes CNE1 and the second connection electrode CNE2 and may surround the side surfaces of the first connection electrodes CNE1 and the second connection electrode CNE2. The first insulating layer IL1 may expose the top surfaces (or upper surfaces) of the first connection electrodes CNE1 and the second connection electrode CNE2.

The first electrodes ET1 may be disposed on the first connection electrodes CNE1 and the first insulating layer IL1. For example, the first electrodes ET1 may be disposed on the respective first connection electrodes CNE1 and may also be disposed on portions of the first insulating layer IL1 around the first connection electrodes CNE1.

The first electrodes ET1 may be disposed between the respective first connection electrodes CNE1 and the respective light emitting elements LE. The first electrodes ET1 may be electrically connected between the respective first connection electrodes CNE1 and the respective light emitting elements LE (e.g., a first semiconductor layer SEM1 or contact electrodes CTE of the respective light emitting elements LE).

The first electrodes ET1 may include a conductive material. The first electrodes ET1 may be bonding electrodes (or bonding pads) for stably disposing or bonding the light emitting elements LE on the backplane substrate BPL. However, the types of the first electrodes ET1 are not limited thereto, and the types, structures, and/or materials of the first electrodes ET1 may vary according to the bonding (or coupling) structure, the bonding (or coupling) method, or the like between the backplane substrate BPL and the light emitting elements LE. Hereinafter, an embodiment in which the first electrodes ET1 are bonding electrodes is described.

The first electrodes ET1 may include a conductive material suitable for the bonding process. For example, the first electrodes ET1 may include a metal or metal alloy with excellent electrical and thermal conductivity, or may include a transparent conductive material that allows a bonding process. Examples of metals or metal alloys that may be included in the first electrodes ET1 include eutectic metals, such as gold (Au)-tin (Sn) alloy, titanium (Ti), zirconium (Zr), nickel (Ni), or chromium (Cr). Examples of transparent conductive materials that may be included in the first electrodes ET1 may include indium tin oxide (ITO), zinc oxide (ZnO), or the like. The first electrodes ET1 may also be formed of other conductive materials. The first electrodes ET1 may have a thickness (e.g., a thickness of about several hundred nanometers) sufficient to properly or readily perform a bonding process.

The first reflective layers RFL1 may be disposed on the respective first electrodes ET1. The first reflective layers RFL1 may include a conductive material, and thus may have conductivity.

The first reflective layers RFL1 may include a conductive material (e.g., metal) with high light reflectivity. For example, the first reflective layers RFL1 may include aluminum (Al) or may include other metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr)) with high light reflectivity. In another embodiment, the first reflective layers RFL1 may be distributed Bragg reflectors (DBR) in which transparent conductive layers with different refractive indices are alternately and/or repeatedly stacked.

Although FIG. 2 discloses an embodiment in which each of the pixels PX includes the first electrode ET1 and the first reflective layer RFL1, the embodiments are not limited thereto. For example, the first electrode ET1 and the first reflective layer RFL1 may be integrated into one electrode (or conductive layer), or the first electrode ET1 may be formed of multiple layers including the first reflective layer RFL1.

The first reflective layers RFL1 may cover (or completely cover) the bottom surface (or lower surface) of each of the light emitting elements LE. Accordingly, the light that has traveled downward from each of the light emitting elements LE may be effectively reflected so that the light efficiency of the pixels PX may be increased.

The light emitting elements LE may be disposed on the respective first reflective layers RFL1. Each of the light emitting elements LE may include the first semiconductor layer SEM1, a light emitting layer EML, and a second semiconductor layer SEM2 sequentially disposed on the first reflective layer RFL1. Each of the light emitting elements LE may further include the contact electrode CTE covering a surface (e.g., the bottom surface (or lower surface)) of the first semiconductor layer SEM1. In another embodiment, each of the light emitting elements LE may not include the contact electrode CTE.

The contact electrode CTE may be disposed on the first reflective layer RFL1 of each pixel PX. The contact electrode CTE may be disposed on a surface (e.g., bottom surface (or lower surface)) of the first semiconductor layer SEM1 included in the light emitting element LE. The contact electrode CTE may protect the first semiconductor layer SEM1 and may smoothly connect the light emitting element LE to each first reflective layer RFL1 (or first electrode ET1).

The contact electrode CTE may include metal, metal oxide, or other conductive materials. The contact electrode CTE may include a transparent conductive material (e.g., indium tin oxide (ITO), indium zinc oxide (IZO), or another transparent conductive material), but is not limited thereto.

The first semiconductor layer SEM1, the light emitting layer EML, and the second semiconductor layer SEM2 may be formed from a semiconductor thin film layer (semiconductor epitaxial stack) or epi-layers formed by epitaxial growth on a semiconductor substrate.

The first semiconductor layer SEM1 may include a semiconductor material doped with a first conductivity type dopant. For example, the first semiconductor layer SEM1 may be a semiconductor layer of a first conductivity type that includes a nitride-based semiconductor material, a phosphide-based semiconductor material, or another semiconductor material and that further includes a dopant of a first conductivity type. The first semiconductor layer SEM1 may be a p-type semiconductor layer (e.g., p-GaN) doped with a p-type dopant such as Mg, Zn, Ca, Se, and Ba.

The light emitting layer EML may be disposed on the first semiconductor layer SEM1. For example, the light emitting layer EML may be disposed between the first semiconductor layer SEM1 and the second semiconductor layer SEM2. The light emitting layer EML may emit light by recombination of electron-hole pairs generated in response to an electrical signal applied through the first semiconductor layer SEM1 and the second semiconductor layer SEM2.

The light emitting layer EML may include a nitride-based semiconductor material, a phosphide-based semiconductor material, or another semiconductor material, and may have a single or multiple quantum well structure. The light emitting layer EML may have a multiple quantum well structure including a quantum well layer including InGaN and a barrier layer including GaN, AlGaN, or GaAlN, but is not limited thereto.

The pixels PX may include the light emitting elements LE that emit light in substantially the same wavelength band. The light emitted by each of the light emitting elements LE may be light having a short wavelength that is equal to or less than the wavelength band of light ultimately emitted from each pixel PX. The first pixel PX1, the second pixel PX2, and the third pixel PX3 may emit red light (e.g., red light with a peak wavelength in the range of about 610 nm to about 650 nm), green light (e.g., green light with a peak wavelength in the range of about 510 nm to about 550 nm), and blue light (e.g., blue light with a peak wavelength in the range of about 440 nm to about 480 nm), respectively. Each of the light emitting elements LE may be a blue light emitting diode (blue LED) or an ultraviolet light emitting diode (UV LED) that emits blue light or ultraviolet light (e.g., ultraviolet light with a peak wavelength in the range of about 100 nm to about 400 nm) having a wavelength band equal to or less than the wavelength band of blue light emitted from the third pixel PX.

In case that the light emitting layer EML includes InGaN, the wavelength band or color of light emitted from the light emitting layer EML may be adjusted by controlling the content of indium (In). In an example, the indium content of the light emitting layer EML may be 10% or less, and the light emitting layer EML may emit ultraviolet light. In another embodiment, the indium content of the light emitting layer EML may be 10% to about 20%, and the light emitting layer EML may emit blue light. In an example, the light emitting layer EML may emit ultraviolet or blue light with a peak wavelength in the range of about 340 nm to about 460 nm.

The light emitting elements LE may be micro light emitting diodes having a fine size of about several micrometers to several hundred micrometers or less. For example, each of the light emitting elements LE may be a UV micro light emitting diode or a blue micro light emitting diode having a length of 100 μm or less in each of the first direction DR1, the second direction DR2, and the third direction DR3.

The second semiconductor layer SEM2 may include a semiconductor material doped with a second conductivity type dopant. For example, the second semiconductor layer SEM2 may be a semiconductor layer of a second conductivity type that includes a nitride-based semiconductor material, a phosphide-based semiconductor material, or another semiconductor material and further includes a dopant of a second conductivity type. The second semiconductor layer SEM2 may be an n-type semiconductor layer (e.g., n-GaN) doped with an n-type dopant such as Si, Ge, and Sn.

The protective film PRL may surround the side surfaces of the light emitting elements LE, the first reflective layers RFL1, and the first electrodes ET1. The protective film PRL may be individually disposed in each pixel area, but is not limited thereto.

The protective film PRL may include an opening that exposes a portion, e.g., the top surface (or upper surface), of each of the light emitting elements LE. In the opening of the protective film PRL, the light emitting elements LE may be electrically connected to the respective second electrodes ET2.

The protective film PRL may include at least one insulating material selected from silicon oxide (SiOₓ), silicon nitride (SiNₓ), silicon oxynitride (SiOₓN_{y}), aluminum oxide (AlₓO_{y}), titanium oxide (TiₓO_{y}), and hafnium oxide (HfOₓ), or another insulating material. The protective film PRL may protect the light emitting elements LE and may improve the electrical stability of the light emitting elements LE.

The second electrodes ET2 may be disposed on the respective light emitting elements LE. For example, the second electrodes ET2 may be disposed on the second semiconductor layers SEM2 of the light emitting elements LE, and may cover the top surfaces (or upper surfaces) of the light emitting elements LE. The second electrodes ET2 may be electrically connected to the second semiconductor layers SEM2 of the light emitting elements LE.

The second electrodes ET2 may also be disposed on top of the protective film PRL and may be electrically connected to the power line PL on the side surfaces thereof. The second electrodes ET2 may be individually formed in the respective pixel areas and electrically connected to the backplane power line BLI through the power line PL.

In another embodiment, the second electrodes ET2 may be formed as one common layer (e.g., the common electrode) disposed across the entire display area DA, and the pixels PX may share one second electrode ET2. The shape or position of the second electrodes ET2, the connection structure between the second electrodes ET2 and the light emitting elements LE, the connection structure between the second electrodes ET2 and the power line PL, and the like may be variously changed according to embodiments.

The second electrodes ET2 may include a transparent conductive material. For example, the second electrodes ET2 may include indium tin oxide (ITO), indium zinc oxide (IZO), or other transparent conductive materials and may be substantially transparent. Accordingly, light generated in the light emitting elements LE may pass through the second electrodes ET2.

The second reflective layers RFL2 may be disposed on the respective second electrodes ET2. The second reflective layers RFL2 may cover (or completely cover) the top surface (or upper surface) of each of the light emitting elements LE.

The second reflective layers RFL2 may be distributed Bragg reflectors. For example, the second reflective layers RFL2 may include first layers and second layers having different refractive indices and alternately stacked above the light emitting elements LE (e.g., on the respective second electrodes ET2) to form a distributed Bragg reflector. The second reflective layers RFL2 may include oxide. For example, each first layer may be made of titanium oxide such as TiO₂, and each second layer may be made of silicon oxide such as SiO₂.

The reflectivity of the first reflective layers RFL1 and the reflectivity of the second reflective layers RFL2 for the emission wavelength of light (e.g., ultraviolet or blue light) emitted from the light emitting elements LE may be different. The first reflective layers RFL1 and the second reflective layers RFL2 may have optimized reflectivity to improve the resonance effect of light emitted from the light emitting elements LE.

The reflectivity of the first reflective layers RFL1 may be higher than the reflectivity of the second reflective layers RFL2. For example, the first reflective layers RFL1 may reflect light emitted from the respective light emitting elements LE at a reflectivity of about 90% or more, and the second reflective layers RFL2 may reflect light emitted from the respective light emitting elements LE at a reflectivity of about 80% or more, and may have a lower reflectivity than the reflectivity of the first reflective layers RFL1. However, the material and reflectivity of each of the first reflective layers RFL1 and the second reflective layers RFL2 may vary depending on embodiments. By disposing a pair of the first reflective layer RFL1 and the second reflective layer RFL2 with different reflectivities on both sides of each of the light emitting elements LE, the amount of light emitted from the light emitting element layer LEL may be increased and the light efficiency of the pixels PX may be increased.

Each light emitting element LE may be a resonant light emitting diode (hereinafter, resonant LED) with an improved or optimized resonance effect due to the first reflective layer RFL1 and the second reflective layer RFL2. In another embodiment, the light emitting element LE, the second electrode ET2 on the light emitting element LE, and the first reflective layer RFL1 (or a lower electrode including the first reflective layer RFL1 and the first electrode ET1) and the second reflective layer RFL2 disposed on both sides of the light emitting element LE may be considered to form a resonant LED.

The power line PL may surround the light emitting elements LE, the protective film PRL, and the second electrodes ET2. For example, the power line PL may be disposed on the side surfaces of the protective film PRL and the second electrodes ET2. The power line PL may further surround the side surfaces of the second reflective layers RFL2.

The power line PL may be electrically connected to the second electrodes ET2. In an example, the power line PL may be directly disposed on the side surfaces of the second electrodes ET2 to be electrically connected to the second electrodes ET2.

The power line PL may be electrically connected to the backplane power line BLI formed in the backplane substrate BPL, inside and/or outside (e.g., in the peripheral area PHA of FIG. 1) the display area DA. FIG. 2 illustrates an embodiment in which the power line PL is electrically connected to the backplane power line BLI inside the display area DA.

The power line PL may include a conductive material (for example, metal). For example, the power line PL may include at least one of gold (Au), copper (Cu), tin (Sn), titanium (Ti), aluminum (Al), or silver (Ag).

The power line PL may include a conductive material having high reflectivity. In an example, the power line PL may include a conductive material, e.g., aluminum (Al), with high reflectivity for the emission wavelength of the light emitting elements LE, or another highly reflective conductive material.

The power line PL may reflect and recirculate light generated in each of the light emitting elements LE and directed in a lateral direction or the like. For example, light generated in each of the light emitting elements LE and directed in a lateral direction may be reflected one or multiple times by the power line PL and emitted toward the top of each of the light emitting elements LE. The light emitted toward the top of the light emitting elements LE may be incident on the respective color conversion layers CCL.

The power line PL may increase the light emission rate of light generated in each of the light emitting elements LE. Accordingly, the amount of light incident on each of the color conversion layers CCL may be increased and the light efficiency of the pixels PX may be improved.

The second insulating layer IL2 may be disposed around the light emitting elements LE. For example, the second insulating layer IL2 may be filled in a space formed between the light emitting elements LE.

The second insulating layer IL2 may be formed at a height greater than or equal to the height of other elements disposed in the light emitting element layer LEL. For example, the second insulating layer IL2 may be formed at a height greater than the highest level of the second reflective layers RFL2 and the power line PL, and may entirely cover other elements (e.g., the light emitting elements LE, the second reflective layers RFL2, and the like) disposed in the light emitting element layer LEL.

The second insulating layer IL2 may include an inorganic insulating material and may be planarized through a planarization process (e.g., a CMP process). Accordingly, the top surface (or upper surface) of the second insulating layer IL2 may be substantially flat.

The second insulating layer IL2 may include oxide capable of oxide-oxide bonding. The second insulating layer IL2 may be optically transparent to allow light emitted from the light emitting element layer LEL to pass therethrough. For example, the second insulating layer IL2 may include an inorganic insulating material including oxide. In an example, the second insulating layer IL2 may include silicon oxide such as SiO₂, aluminum oxide such as Al₂O₃, or another oxide capable of oxide-oxide bonding. The second insulating layer IL2 may also be referred to as “first oxide layer.”

The light conversion layer CVTL may be disposed on the light emitting element layer LEL. The light conversion layer CVTL may include the color conversion layers CCL disposed above the light emitting elements LE of the pixels PX, third reflective layers RFL3 surrounding the color conversion layers CCL, and the third insulating layer IL3 disposed around the color conversion layers CCL and the third reflective layers RFL3.

The color conversion layers CCL may overlap the light emitting elements LE in the third direction DR3. The color conversion layers CCL may include a first color conversion layer CCL1 disposed above the light emitting element LE of each of the first pixels PX1, a second color conversion layer CCL2 disposed above the light emitting element LE of each of the second pixels PX2, and a third color conversion layer CCL3 disposed above the light emitting element LE of each of the third pixels PX3. The first color conversion layer CCL1, the second color conversion layer CCL2, and the third color conversion layer CCL3 may absorb light emitted from the respective light emitting elements LE and convert it into light of the first color, light of the second color, and light of the third color, respectively.

Each color conversion layer CCL may include an inorganic material (e.g., a nitride-based semiconductor material) and may have a multiple quantum well structure. The color conversion layer CCL may absorb light of a short wavelength emitted from each light emitting element LE and emit light of a longer wavelength. The color conversion layer CCL may also be referred to as “wavelength conversion layer.” For example, each color conversion layer CCL may absorb light emitted from each light emitting element LE and use it as an excitation source, thereby converting it into light corresponding to the emission wavelength of the corresponding pixel PX. The light converted by each color conversion layer CCL may be emitted toward the top (e.g., vertically) of the pixels PX in the third direction DR3 or the like.

Each color conversion layer CCL may have a volume sufficient to ensure light conversion efficiency. For example, the height or thickness of the color conversion layer CCL may be larger than the height or thickness of the light emitting element LE. The total volume of quantum well layers included in each color conversion layer CCL may be larger than the total volume of quantum well layers included in the light emitting layer EML of the light emitting element LE.

The third reflective layers RFL3 may surround the color conversion layers CCL. For example, the third reflective layers RFL3 may surround the side surfaces of the first color conversion layer CCL1, the second color conversion layer CCL2, and the third color conversion layer CCL3.

The third insulating layer IL3 may be disposed around the color conversion layers CCL. For example, the third insulating layer IL3 may be filled in a space formed between the color conversion layers CCL.

The third insulating layer IL3 may be formed with a thickness greater than or equal to the thickness of other elements disposed in the light conversion layer CVTL. For example, the third insulating layer IL3 may be formed with a thickness greater than the thickness of the color conversion layers CCL and the third reflective layers RFL3, and may cover the bottom surfaces (or lower surfaces) of the color conversion layers CCL and the third reflective layers RFL3.

The third insulating layer IL3 may include an inorganic insulating material and may be planarized through a planarization process (e.g., a CMP process). Accordingly, the bottom surface (or lower surface) of the third insulating layer IL3 may be substantially flat.

The third insulating layer IL3 may include oxide capable of oxide-oxide bonding. The third insulating layer IL3 may be optically transparent to allow light emitted from the light emitting element layer LEL to pass therethrough. For example, the third insulating layer IL3 may include an inorganic insulating material including oxide. In an example, the third insulating layer IL3 may include silicon oxide such as SiO₂, aluminum oxide such as Al₂O₃, or another oxide capable of oxide-oxide bonding. The third insulating layer IL3 may also be referred to as “second oxide layer.” The second insulating layer IL2 and the third insulating layer IL3 may include the same material, e.g., SiO₂, and may be bonded together.

The light emitting element layer LEL and the light conversion layer CVTL may be individually formed on different substrates and may be bonded together through oxide-oxide bonding of the second insulating layer IL2 and the third insulating layer IL3. Accordingly, a bonding interface BIF may exist between the second insulating layer IL2 and the third insulating layer IL3. An insulating layer (e.g., a portion of the second insulating layer IL2 and the third insulating layer IL3) including oxide may be present between the color conversion layer CCL and the second reflective layer RFL2 of each pixel PX.

The third reflective layers RFL3 may include a conductive material (e.g., metal) with high light reflectivity. For example, the third reflective layers RFL3 may include aluminum (Al) or may include other metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr)) with high light reflectivity. However, the embodiments are not limited thereto. For example, the third reflective layers RFL3 may be formed as distributed Bragg reflectors.

The color filters CF may be disposed on the light conversion layer CVTL. The color filters CF may include a first color filter CF1 disposed on the first color conversion layer CCL1, a second color filter CF2 disposed on the second color conversion layer CCL2, and a third color filter CF3 disposed on the third color conversion layer CCL3. The bottom surface (or lower surface) of each of the color filters CF may cover (or completely cover) the top surface (or upper surface) of each of the color conversion layers CCL. Accordingly, light loss of the pixels PX may be prevented or reduced.

Each of the color filters CF may be an optical filter capable of blocking (e.g., blocking or absorbing) light in a wavelength band emitted from the light emitting elements LE and transmitting light in a wavelength band converted by each of the color conversion layers CCL. For example, each of the color filters CF may be an optical filter, e.g., an ultraviolet blocking filter, that blocks ultraviolet light or light in a wavelength band corresponding to an emission wavelength λ (e.g., a peak wavelength band) of the light emitting elements LE.

The first color filter CF1 may transmit light of the first color, for example, red light. The second color filter CF2 may transmit light of the second color, for example, green light. The third color filter CF3 may transmit light of the third color, for example, blue light. The first color filter CF1, the second color filter CF2, and the third color filter CF3 may be a red color filter, a green color filter, and a blue color filter, respectively, but are not limited thereto. For example, the first color filter CF1, the second color filter CF2, and the third color filter CF3 may be formed as distributed Bragg reflectors optimized for the emission wavelength of each pixel PX, or may include an organic material.

The lens LS may be disposed on each color filter CF. The lens LS may have a size (or diameter) corresponding to the area (or diameter) of the color conversion layer CCL and the light emitting element LE of each pixel PX, and may overlap the color conversion layer CCL and the light emitting element LE of each pixel PX in the third direction DR3. For example, the lens LS may be a microlens corresponding to the size (or diameter) of each of the light emitting elements LE. Each lens LS may have a size (or diameter) larger than each light emitting element LE and each color conversion layer CCL in a plan view, and may cover the periphery of the light emitting element LE and the color conversion layer CCL. The lens LS may be a microlens in the form of a convex lens, but is not limited thereto. By disposing the lens LS on top of each color conversion layer CCL and color filter CF, the light emission characteristics of the pixels PX may be adjusted or improved.

The lens LS may be formed of a transparent material such that light incident from the light emitting elements LE may be transmitted. As an example, the lens LS may be formed of glass, plastic, ceramic, or other materials, and may be formed of an optical material with a high refractive index.

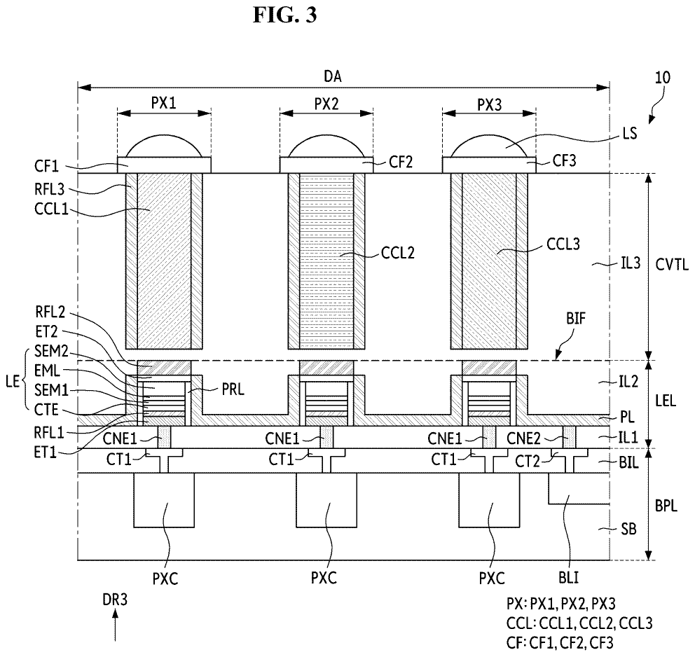

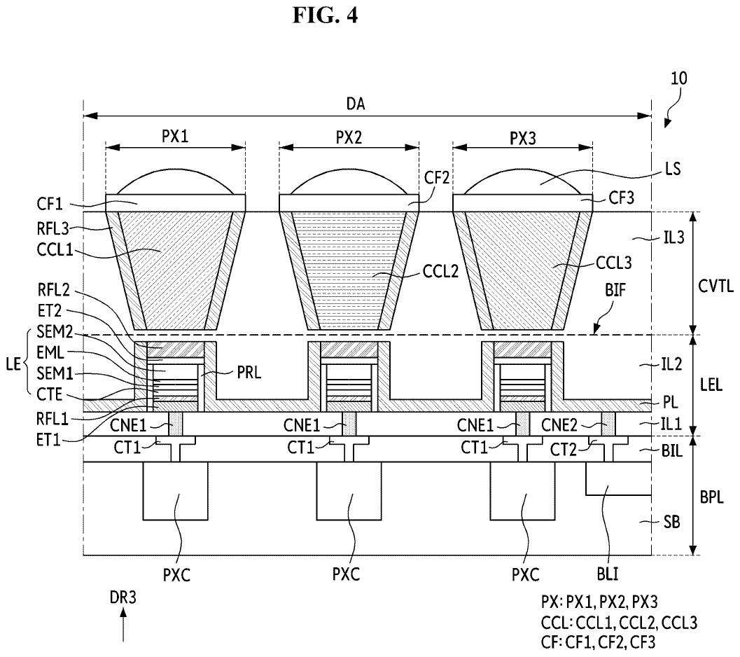

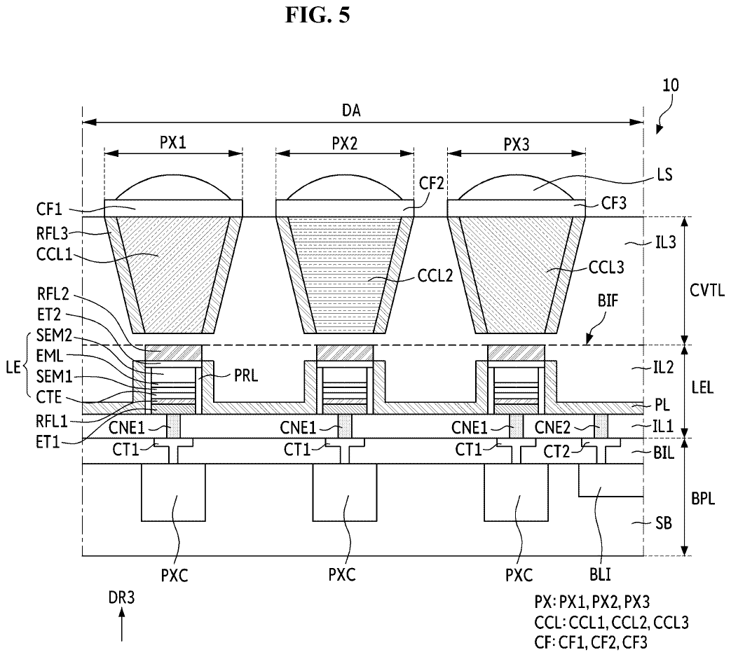

FIG. 3 is a schematic cross-sectional view illustrating a display device according to an embodiment. FIG. 4 is a schematic cross-sectional view illustrating a display device according to an embodiment. FIG. 5 is a schematic cross-sectional view illustrating a display device according to an embodiment.

For example, FIGS. 3, 4, and 5 illustrate a portion of the display area DA of FIG. 1, and show a schematic cross-section of the first pixel PX1, the second pixel PX2, and the third pixel PX3, which form one unit pixel UPX among the pixels PX in the display area DA. FIG. 3 shows the display device 10 in which the position of the bonding interface BIF is different from that of FIG. 2. FIGS. 4 and 5 show the display device 10 in which the shape and size of the color conversion layers CCL are different from those of FIGS. 2 and 3. In describing the embodiments, components similar or identical to those of at least one embodiment described above are designated with the same reference numerals, and redundant descriptions will be omitted.

Referring to FIG. 3, the second insulating layer IL2 may be formed at the same height as the second reflective layers RFL2, and the bonding interface BIF may be located on the top surface (or upper surface) of each of the second reflective layers RFL2. For example, if an oxide layer (e.g., a second layer including oxide such as SiO₂) capable of oxide-oxide bonding is disposed in the uppermost portion of each of the second reflective layers RFL2, the second insulating layer IL2 and the second reflective layers RFL2 may be formed at the same height. Accordingly, the second insulating layer IL2 may expose the top surfaces (or upper surfaces) of the second reflective layers RFL2, and the top surfaces (or upper surfaces) of the second insulating layer IL2 and the second reflective layers RFL2 may be bonded to the third insulating layer IL3 through oxide-oxide bonding.

Referring to FIGS. 4 and 5, the color conversion layers CCL may have a reverse tapered cross-section. For example, the color conversion layers CCL may be formed as truncated solids with a shape that gradually decreases in width toward the bottom. The third reflective layers RFL3 may surround the side surface of each of the color conversion layers CCL and may have a shape and size corresponding to the color conversion layers CCL.

The bottom surface (or lower surface) of each of the color conversion layers CCL may have an area greater than or equal to the area of the top surface (or upper surface) of each of the second reflective layers RFL2 or the light emitting elements LE, and may cover (or completely cover) the second reflective layers RFL2 or the light emitting elements LE in a plan view. The bottom surface (or lower surface) of each of the color filters CF may cover (or completely cover) the top surface (or upper surface) of each of the color conversion layers CCL. Accordingly, light loss of the pixels PX may be prevented or reduced.

The color conversion layers CCL may have a volume sufficient to ensure light conversion efficiency. In case that the area or width of the color conversion layers CCL increases in the embodiments of FIGS. 4 and 5 compared to the embodiments of FIGS. 2 and 3, the height or thickness of the color conversion layers CCL may decrease. However, the embodiments are not limited thereto, and the shape or size of the color conversion layers CCL may vary depending on embodiments.

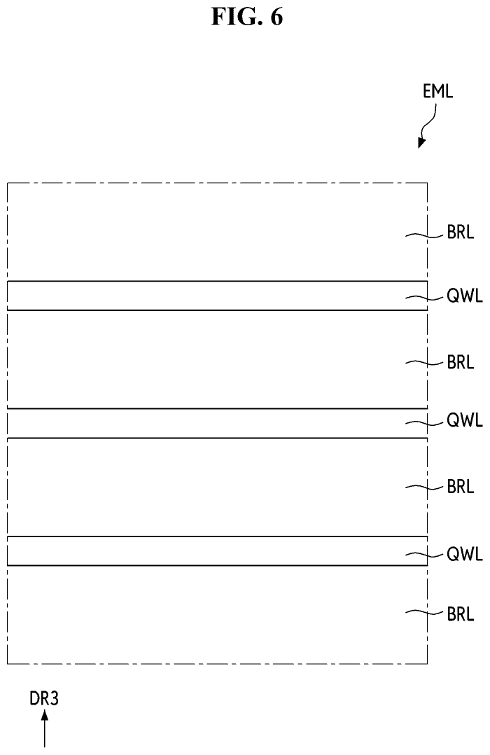

FIG. 6 is a schematic cross-sectional view showing a light emitting layer according to an embodiment. For example, FIG. 6 shows the light emitting layer EML of each of the light emitting elements LE disposed in the light emitting element layer LEL of FIGS. 2 to 5.

Referring to FIG. 6, the light emitting layer EML may have a single or multiple quantum well structure including at least one quantum well layer QWL. For example, the light emitting layer EML may have a multiple quantum well structure including the quantum well layers QWL and barrier layers BRL. The quantum well layers QWL and the barrier layers BRL may be alternately disposed or stacked in the third direction DR3. The barrier layers BRL may be disposed as the lowermost layer and the uppermost layer of the light emitting layer EML.

The quantum well layer QWL may include a nitride-based semiconductor material. In an example, the quantum well layer QWL may include GaN, InGaN, AlGaN, or AlInGaN. The quantum well layer QWL may include little indium or include indium at a low content, depending on the emission wavelength. In case that the light emitting element LE emits ultraviolet light, the quantum well layer QWL may include substantially no indium, or may include indium at a low content (or composition) of about 10% or less. In case that the light emitting element LE emits blue light, the quantum well layer QWL may include indium at a content of about 10% to about 20%.

The barrier layer BRL may include a nitride-based semiconductor material. In an example, the barrier layer BRL may include AlGaN or GaN. The materials of the quantum well layer QWL and the barrier layer BRL are not limited to the materials exemplified above, and may vary depending on embodiments.

In case that the light emitting element LE has a small thickness of about 1μm or less, e.g., a thickness of about several hundred nanometers, the light emitting layer EML may have a thickness of about several to about several tens of nanometers. In an example, the total thickness of the light emitting layer EML may be about 10 nm or less.

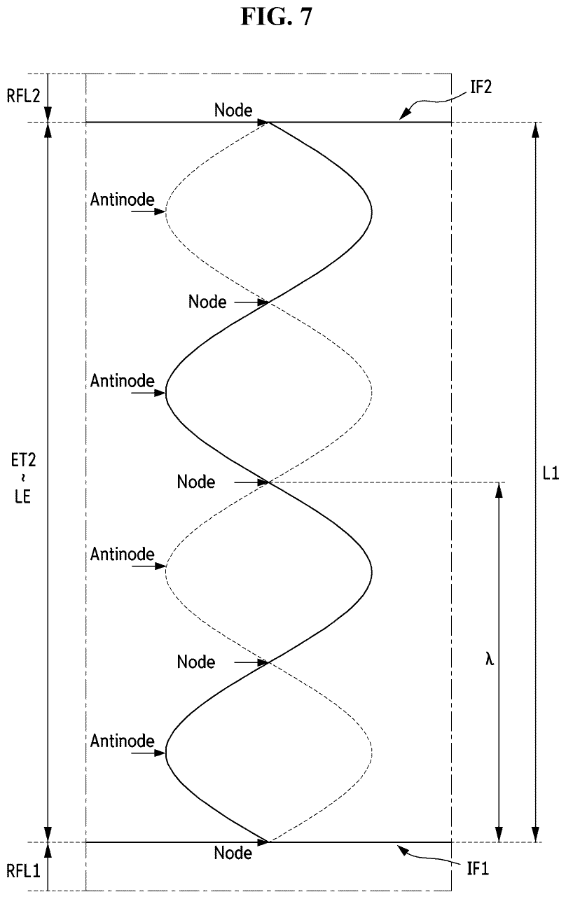

FIG. 7 is a schematic diagram illustrating a resonant structure according to an embodiment. For example, FIG. 7 illustrates a standing wave according to a resonant structure formed between the first reflective layer RFL1 and the second reflective layer RFL2 according to an embodiment.

Referring to FIGS. 1 to 7, the distance between the first reflective layer RFL1 and the second reflective layer RFL2 disposed on both sides of the light emitting element LE may be appropriately adjsted according to the emission wavelength λ of the light emitting element LE. For example, the distance between the first reflective layer RFL1 and the second reflective layer RFL2 may be set to a value corresponding to a first length L1, which corresponds to N (where N is a natural number) times the emission wavelength λ of the light emitting element LE. In an example, a first interface IF1 between the first reflective layer RFL1 and the light emitting element LE and a second interface IF2 between the second reflective layer RFL2 and the second electrode ET2 may be located at a point (or height) corresponding to a node at which the amplitude of the emission wavelength λ of the light emitting element LE is minimized.

Each of the light emitting elements LE may be an ultra-small nano LED or micro LED having a thickness of about 1 μm or less. For example, the thickness of each of the light emitting elements LE or the first length L1 may be several hundred nanometers. Each of the light emitting elements LE may emit light in response to an electrical signal applied to both ends thereof, and may emit sufficient light to be used as a light source for the pixels PX even though it is formed in an ultra-small size. By using the light emitting elements LE having ultra-small sizes, it is possible to readily manufacture the high-resolution display device 10 (e.g., a virtual reality device or an augmented reality device) of a fine size.

In FIG. 7, the first reflective layer RFL1 and the second reflective layer RFL2 may be shown as being spaced apart from each other by a distance equal to the first length L1 corresponding to twice the emission wavelength λ of the light emitting element LE, but the embodiments are not limited thereto. In an example, the first reflective layer RFL1 and the second reflective layer RFL2 may be spaced apart from each other by a distance corresponding to three times or more the emission wavelength λ of the light emitting element LE.

Between the first reflective layer RFL1 and the second reflective layer RFL2, the light emitting element LE and the second electrode ET2 may be disposed. The light efficiency of the light emitting element LE may be improved or optimized by appropriately adjusting or optimizing the thicknesses of multiple layers included in the light emitting element LE and the second electrode ET2. For example, the quantum well layers QWL included in the light emitting element LE may be located at a point (or height) corresponding to an antinode at which the amplitude of the emission wavelength λ (or wave) of the light emitting element LE is maximized. Accordingly, the resonance of the light generated in the light emitting element LE may be enhanced and the light efficiency of the light emitting element LE may be improved.

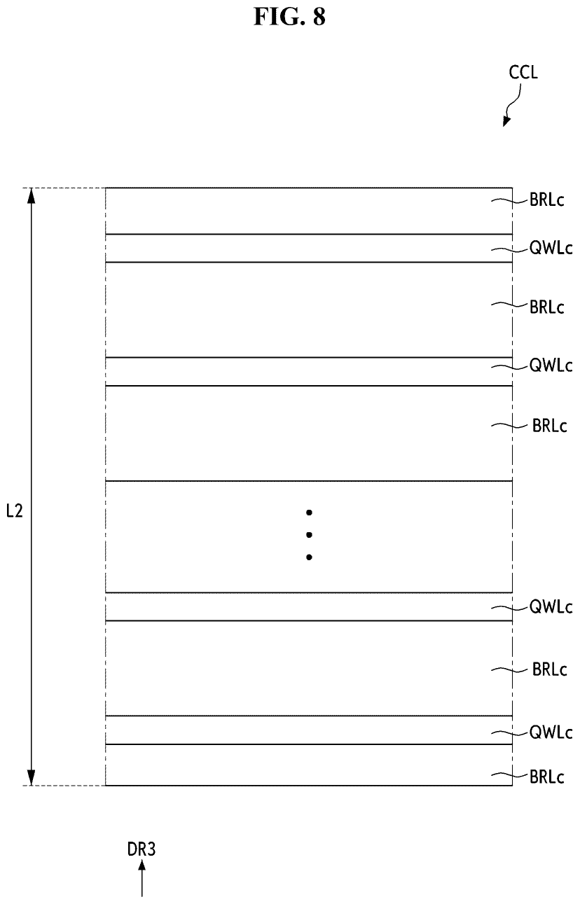

FIG. 8 is a schematic cross-sectional view illustrating a color conversion layer according to an embodiment. For example, FIG. 8 shows a cross-section of each of the color conversion layers CCL disposed in the light conversion layer CVTL of FIGS. 2 to 5.

Referring to FIG. 8, the color conversion layer CCL may have a multiple quantum well structure including quantum well layers QWLc and barrier layers BRLc. The quantum well layers QWLc and the barrier layers BRLc may be alternately disposed or stacked in the third direction DR3. The barrier layers BRLc may be disposed as the lowermost layer and the uppermost layer of the color conversion layer CCL. Each color conversion layer CCL may include a nitride-based semiconductor material.

The quantum well layer QWLc may include a nitride-based semiconductor material including indium. As an example, the quantum well layer QWLc may include InGaN, but is not limited thereto. The indium content (or composition) of the quantum well layer QWLc included in the color conversion layer CCL may be greater than or equal to the indium content (or composition) of the quantum well layer QWL included in the light emitting element LE.

The first color conversion layer CCL1 may include indium at a content corresponding to the wavelength band of the first color light. For example, in case that the first color conversion layer CCL1 absorbs light emitted from the light emitting element LE and converts it to red light (e.g., red light having a peak wavelength in the range of about 610 nm to about 650 nm), the indium content of the quantum well layers QWLc of the first color conversion layer CCL1 may be about 30% to about 40%.

The second color conversion layer CCL2 may include indium at a content corresponding to the wavelength band of the second color light. For example, in case that the second color conversion layer CCL2 absorbs light emitted from the light emitting element LE and converts it to green light (e.g., green light having a peak wavelength in the range of about 510 nm to about 550 nm), the indium content of the quantum well layers QWLc of the second color conversion layer CCL2 may be about 20% to about 30%.

The third color conversion layer CCL3 may include indium at a content corresponding to the wavelength band of the third color light. For example, in case that the third color conversion layer CCL3 absorbs light emitted from the light emitting element LE and converts it to blue light (e.g., blue light having a peak wavelength in the range of about 440 nm to about 480 nm), the indium content of the quantum well layers QWLc of the third color conversion layer CCL3 may be about 10% to about 20%.

The barrier layer BRLc may include a nitride-based semiconductor material. As an example, the barrier layer BRLc may include GaN. However, the materials of the quantum well layer QWLc and the barrier layer BRLc are not limited to those exemplified above and may vary depending on embodiments.

Each barrier layer BRLc may have a thickness that is adjusted or optimized to improve the light conversion efficiency of the color conversion layer CCL. For example, each barrier layer BRLc may have a thickness corresponding to the wavelength band of light emitted from the light emitting element LE. For example, in case that the light emitting element LE emits ultraviolet light, each barrier layer BRLc may have a thickness of about 100 nm or less (e.g., a thickness of about 90 nm or less), and in case that the light emitting element LE emits blue light, each barrier layer BRLc may have a thickness of about 90 nm or more (e.g., a thickness of about 90 nm to about 115 nm).

The barrier layers BRLc disposed as the lowermost and uppermost layers of the color conversion layer CCL may have a smaller thickness than other barrier layers BRLc, for example, about half the thickness of another barrier layers. In an example, in case that the light emitting element LE emits ultraviolet light, each of the barrier layers BRLc disposed as the lowermost and uppermost layers of the color conversion layer CCL may have a thickness of about 50 nm or less (e.g., a thickness of about 45 nm or less), and in case that the light emitting element LE emits blue light, each of the barrier layers BRLc disposed as the lowermost and uppermost layers of the color conversion layer CCL may have a thickness of about 45 nm or more (e.g., a thickness of about 45 nm to about 58 nm). However, the embodiments are not limited thereto, and the thickness of the barrier layers BRLc or the total thickness of the color conversion layer CCL may vary depending on embodiments.

Each color conversion layer CCL may have a thickness adjusted to improve or optimize the light efficiency of the pixel PX. For example, each color conversion layer CCL may have a thickness corresponding to a second length L2 of about 1 μm or more, e.g., a thickness in the range of about 1 μm to about 10 μm. As the color conversion layer CCL has a thickness of about 1 μm or more, color conversion efficiency may be ensured or improved, and as the color conversion layer CCL has a thickness of about 10 μm or less, light loss may be reduced or minimized and optical efficiency may be increased. Accordingly, even if light emitted from each light emitting element LE is converted into light corresponding to the emission wavelength of each pixel PX, the luminance of the pixel PX may be appropriately ensured or improved.

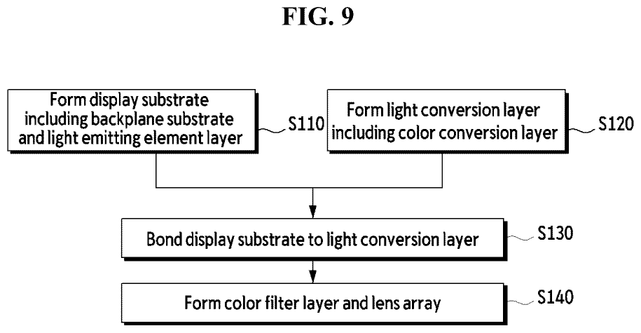

FIG. 9 is a schematic flowchart illustrating a method of manufacturing a display device according to an embodiment. For example, FIG. 9 schematically shows the manufacturing steps of the display device 10 including the color conversion layers CCL, as in the above-described embodiments.

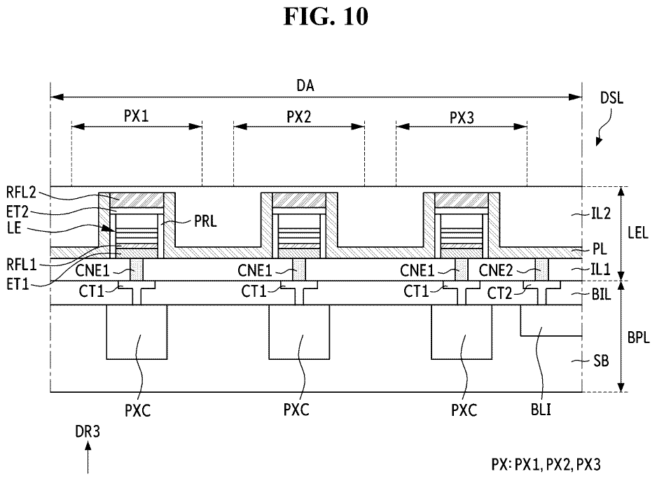

FIG. 10 is a schematic cross-sectional view showing a display substrate according to an embodiment. For example, FIG. 10 shows an embodiment of a display substrate DSL formed in step S110 of FIG. 9.

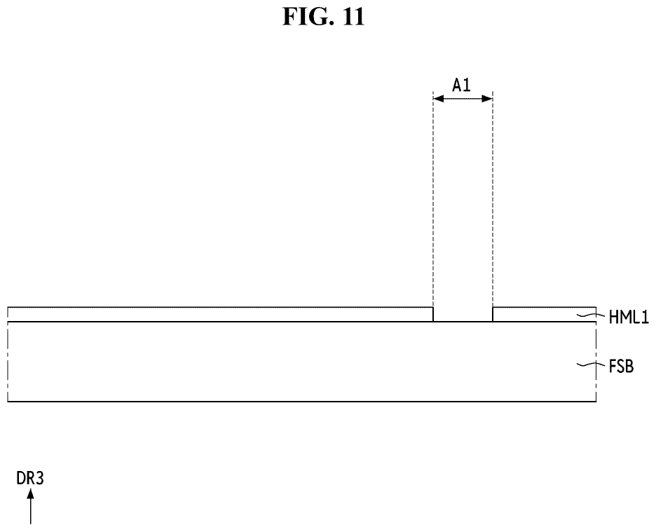

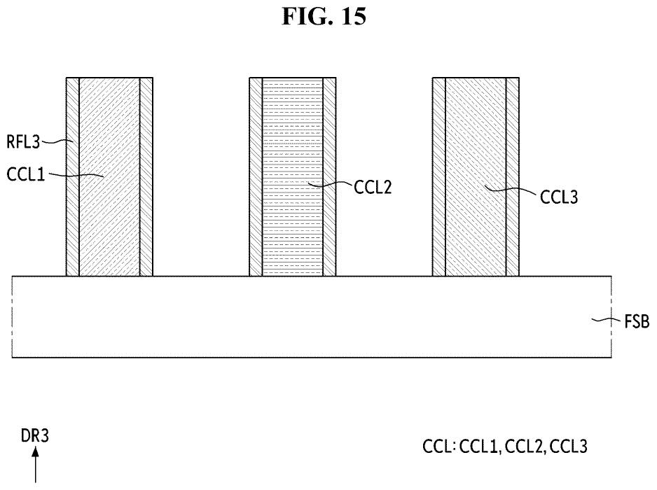

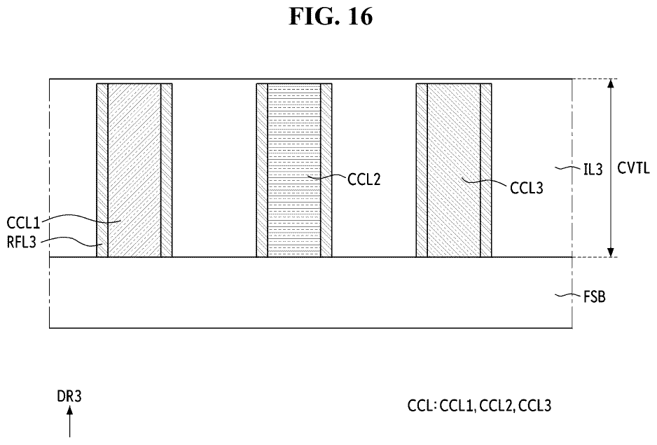

FIGS. 11 to 16 are schematic cross-sectional views sequentially illustrating a method of forming a light conversion layer according to an embodiment. The manufacturing steps shown in FIGS. 11 to 16 may be included in step S120 of FIG. 9.

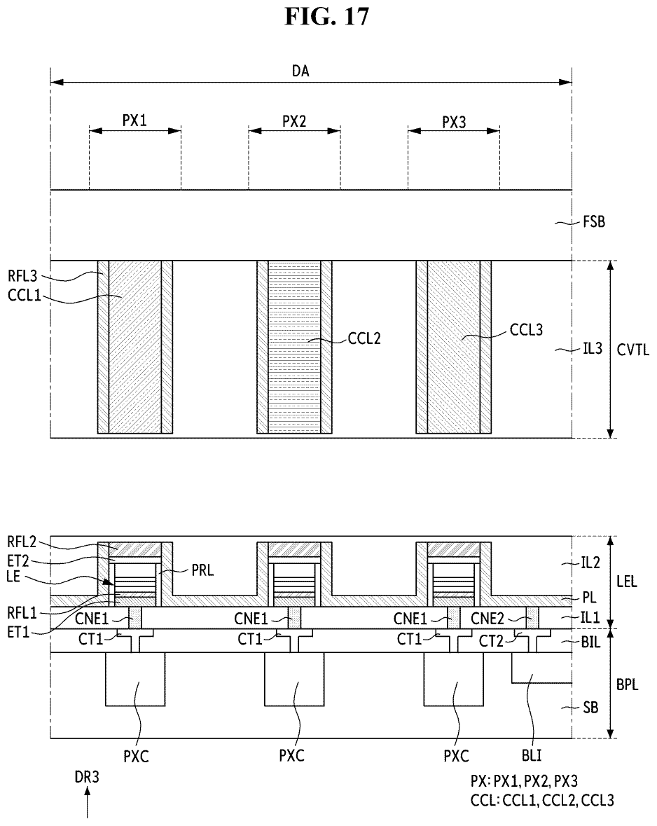

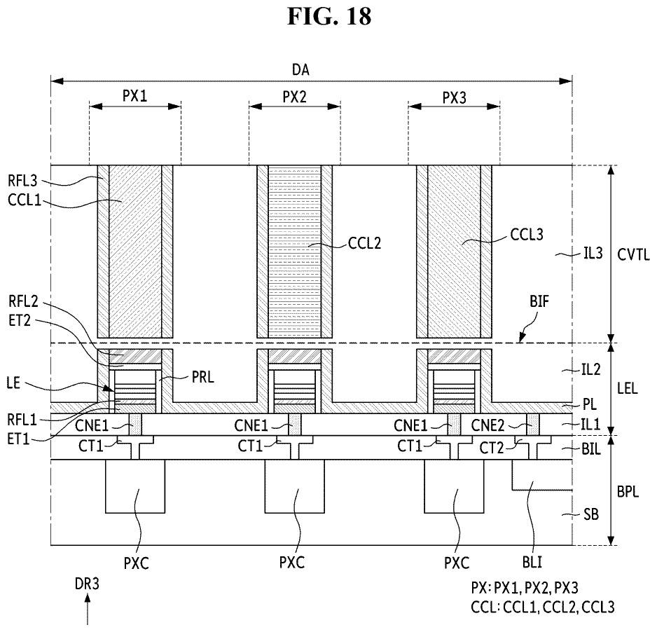

FIGS. 17 and 18 are schematic cross-sectional views sequentially illustrating a method of bonding (or coupling) a display substrate to a light conversion layer according to an embodiment. The manufacturing steps of FIGS. 17 and 18 may be included in step S130 of FIG. 9.

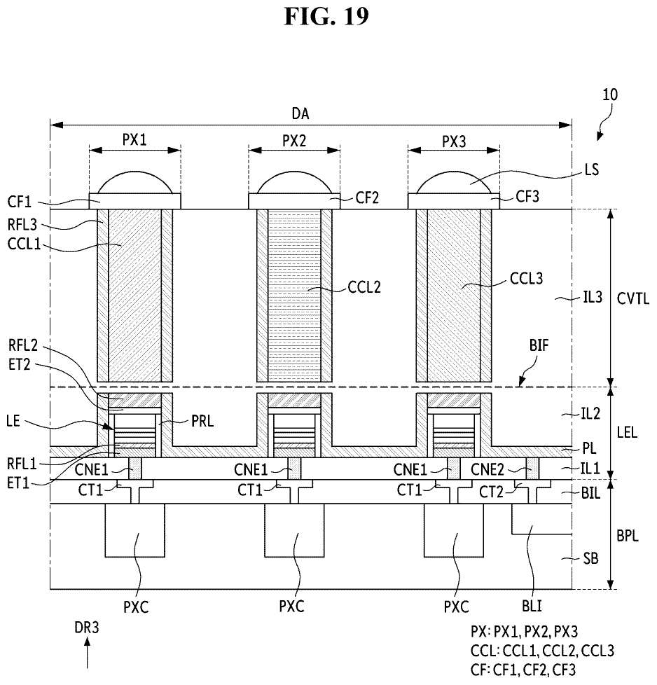

FIG. 19 is a schematic cross-sectional view illustrating a display device manufactured according to an embodiment. FIG. 19 shows a step of forming a color filter layer and a lens array included in step S140 of FIG. 9.

Referring to FIG. 9, a method of manufacturing the display device 10 according to an embodiment may include forming the display substrate including the backplane substrate BPL and the light emitting element layer LEL (step S110), forming the light conversion layer CVTL including the color conversion layer CCL (step S120), bonding (or coupling) the display substrate to the light conversion layer CVTL (step S130), and forming the color filter layer and the lens array (step S140). Steps S110 and S120 may be performed individually or independently, and may be performed simultaneously or sequentially.

Referring to FIGS. 9 and 10, step S110 of forming the display substrate DSL including the backplane substrate BPL and the light emitting element layer LEL may include preparing the backplane substrate BPL and forming the light emitting element layer LEL on the backplane substrate BPL. As shown in FIG. 10, the step of preparing the backplane substrate BPL may be a step of providing or manufacturing the backplane substrate BPL, which includes the pixel circuits PXC, the backplane power line BLI, the first contact terminals CT1, the second contact terminal CT2, and the lower insulating layer BIL. The step of forming the light emitting element layer LEL on the backplane substrate BPL may include: forming the first connection electrodes CNE1, the second connection electrode CNE2, and the first insulating layer IL1 on the backplane substrate BPL; forming the first electrodes ET1, the first reflective layers RFL1, and the light emitting elements LE on the first connection electrodes CNE1; forming the protective film PRL on the side surfaces of the first electrodes ET1, the first reflective layers RFL1, and the light emitting elements LE; forming the second electrodes ET2 and the second reflective layers RFL2 on the light emitting elements LE; forming the power line PL on the second connection electrode CNE2 and the side surfaces of the second electrodes ET2, the protective film PRL, and the like; and forming the second insulating layer IL2.

The light emitting elements LE may be formed by etching a semiconductor thin film layer (or epi-layer) grown on a semiconductor substrate, and the light emitting elements LE may be disposed or bonded onto the first reflective layers RFL1. In another embodiment, a semiconductor thin film layer or epi-layer grown on a semiconductor substrate may be disposed or bonded onto the first connection electrodes CNE1, the second connection electrode CNE2, and the first insulating layer IL1 through a wafer-to-wafer bonding process or the like, and then etched to form the light emitting elements LE. The first electrodes ET1 and the first reflective layers RFL1 may be formed as individual patterns prior to the bonding of the light emitting elements LE or the semiconductor thin film layer, or may be etched into individual patterns after the bonding of the light emitting elements LE or the semiconductor thin film layer.

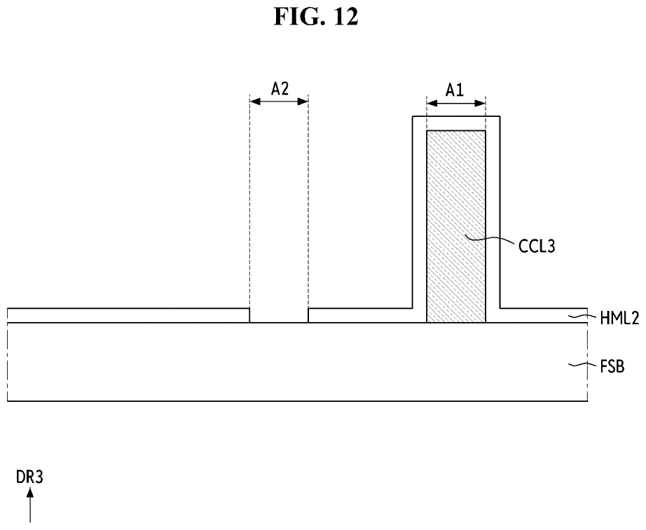

Referring to FIGS. 9, 11, and 14, the color conversion layers CCL may be formed on a manufacturing substrate FSB. The color conversion layers CCL may be formed on different regions of the manufacturing substrate FSB. The formation order of the color conversion layers CCL may be determined based on the wavelength band of light converted by the color conversion layers CCL. In an example, the third color conversion layer CCL3 corresponding to the third color light, which is the shortest wavelength light among the first color light, the second color light, and the third color light, may be formed first. For example, as shown in FIGS. 11 and 12, a first mask layer HML1 exposing a first region A1 may be formed on the manufacturing substrate FSB, and the third color conversion layer CCL3 may be formed in the first region A1.

The manufacturing substrate FSB is a substrate for manufacturing the color conversion layers CCL and may be a growth substrate suitable for epitaxial growth.

The manufacturing substrate FSB may include a material such as GaAs, silicon (Si), sapphire, SiC, GaN, ZnO, or Al₂O₃. If the epitaxial growth of the semiconductor layers for manufacturing the color conversion layers CCL can proceed smoothly, the type or material of the manufacturing substrate FSB is not particularly limited.

The first mask layer HML1 may include an opening corresponding to the first region A1 (e.g., exposing the manufacturing substrate FSB in the first region A1) and may cover other regions of the manufacturing substrate FSB. The first mask layer HML1 may include an inorganic material such as SiO₂ or SiNx, but is not limited thereto. The first mask layer HML1 may be removed after the formation of the third color conversion layer CCL3.

The third color conversion layer CCL3 may be formed by epitaxial growth. For example, the barrier layers BRLc and the quantum well layers QWLc of the third color conversion layer CCL3 may be alternately formed by epitaxial growth using the previously exemplified semiconductor material.

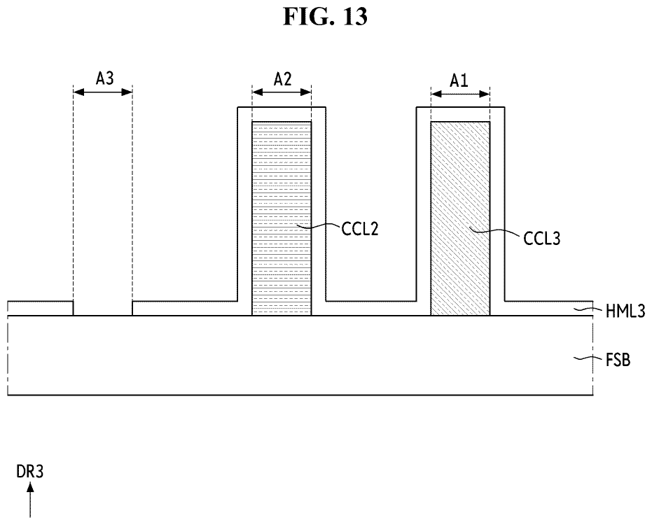

Subsequently, as shown in FIGS. 12 and 13, a second mask layer HML2 exposing a second region A2 may be formed on the manufacturing substrate FSB, and the second color conversion layer CCL2 may be formed in the second region A2. The second mask layer HML2 may include an inorganic material such as SiO₂ or SiNx, but is not limited thereto. The materials of the first mask layer HML1 and the second mask layer HML2 may be the same or different. The second mask layer HML2 may be removed after the formation of the second color conversion layer CCL2.

The second color conversion layer CCL2 may be formed by epitaxial growth. For example, the barrier layers BRLc and the quantum well layers QWLc of the second color conversion layer CCL2 may be alternately formed by epitaxial growth using the previously exemplified semiconductor material.

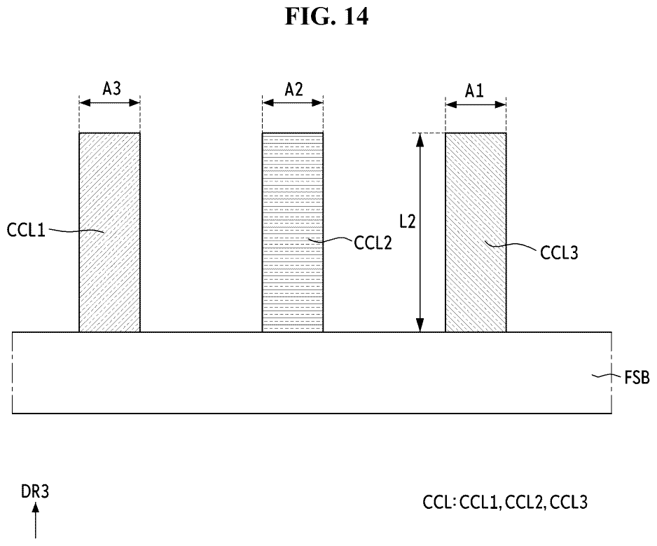

Subsequently, as shown in FIGS. 13 and 14, a third mask layer HML3 exposing a third region A3 may be formed on the manufacturing substrate FSB and the first color conversion layer CCL1 may be formed in the third region A3. The third mask layer HML3 may include an inorganic material such as SiO₂ or SiNx, but is not limited thereto. The material of the third mask layer HML3 may be the same as or different from the material of the first mask layer HML1 and/or the second mask layer HML2. The third mask layer HML3 may be removed after the formation of the first color conversion layer CCL1.

The first color conversion layer CCL1 may be formed by epitaxial growth. For example, the barrier layers BRLc and the quantum well layers QWLc of the first color conversion layer CCL1 may be alternately formed by epitaxial growth using the previously exemplified semiconductor material.

In one embodiment, by forming the color conversion layers CCL using a molecular beam epitaxy (MBE) method, each of the color conversion layers CCL may be formed in a rod shape. In another embodiment, by forming the color conversion layers CCL using a metal-organic chemical vapor deposition (MOCVD) method, each of the color conversion layers CCL may be formed in the shape of a truncated pyramid or another truncated solid. Each of the color conversion layers CCL may be thickly formed to have the second length L2 of 1 μm or more in the third direction DR3.

Referring to FIGS. 9, 11 to 15, the third reflective layer RFL3 may be formed on the side surface of each of the color conversion layers CCL. For example, the third reflective layer RFL3 surrounding the side surface of each of the color conversion layers CCL may be formed using a material previously exemplified as the material of the third reflective layer RFL3.

Referring to FIGS. 9, 11 to 16, the third insulating layer IL3 may be formed on the manufacturing substrate FSB, the color conversion layers CCL, and the third reflective layers RFL3. The third insulating layer IL3 may be formed by a film forming process using the previously exemplified material, and may be formed to a height greater than or equal to the height of the color conversion layers CCL and the third reflective layers RFL3. Accordingly, the third insulating layer IL3 may cover the color conversion layers CCL and the third reflective layers RFL3. A flattening process may be performed to flatten the top surface (or upper surface) of the third insulating layer IL3.

Referring to FIGS. 9 to 17, the display substrate DSL and the light conversion layer CVTL may be disposed to face each other. In an example, the manufacturing substrate FSB with the light conversion layer CVTL formed thereon may be disposed or aligned on the display substrate DSL such that the surface with the light conversion layer CVTL faces the display substrate DSL.

Referring to FIGS. 9 to 18, the display substrate DSL and the light conversion layer CVTL may be bonded (or coupled) together, and the manufacturing substrate FSB may be separated and removed from the light conversion layer CVTL. The display substrate DSL and the light conversion layer CVTL may be bonded (or coupled) through oxide-oxide bonding. For example, by bonding the second insulating layer IL2 to the third insulating layer IL3 through oxide-oxide bonding, the light conversion layer CVTL may be bonded onto the display substrate DSL including the backplane substrate BPL and the light emitting element layer LEL. Accordingly, the light conversion layer CVTL may be disposed or formed on the light emitting element layer LEL. The bonding interface BIF may exist between the second insulating layer IL2 and the third insulating layer IL3.

Referring to FIGS. 9 to 19, the color filter layer including the color filters CF and the lens array including the lens LS may be sequentially formed on the light conversion layer CVTL. The color filters CF and the lens LS may be formed using the previously exemplified material, and may be disposed in the respective pixel areas to cover the respective color conversion layers CCL.

As described above, the display device 10 according to embodiments may include the light emitting elements LE that emit light in the same wavelength band, as a light source for the pixels PX. The light emitting elements LE may be simultaneously formed using the same material. Accordingly, the structure of the light emitting element layer LEL including the light emitting elements LE may be simplified, and the number of mask processes included in the formation process of the light emitting element layer LEL may be reduced. Accordingly, the manufacturing process of the display device 10 may be simplified and manufacturing efficiency may be increased.

In some embodiments, the first reflective layer and the second reflective layer with different reflectivities may be disposed on both sides of each of the light emitting elements LE. Accordingly, the resonance of light generated in each of the light emitting elements LE may be enhanced, and the light efficiency of each of the light emitting elements LE may be improved.

The display device 10 according to embodiments may include the color conversion layers CCL disposed above the light emitting elements LE and converting light emitted from the light emitting elements LE into light corresponding to the emission wavelength of each pixel PX. Accordingly, each of the pixels PX may emit light of a color corresponding to its emission wavelength.

In some embodiments, the color conversion layers CCL may be formed on one manufacturing substrate FSB and covered with an insulating layer (e.g., the third insulating layer IL3) including oxide. The light conversion layer CVTL including the color conversion layers CCL may be bonded onto the light emitting element layer LEL through oxide-oxide bonding. Accordingly, the light emitting element layer LEL and the color conversion layers CCL may be stably bonded (or coupled) or combined, and the manufacturing process of the display device 10 may be facilitated or simplified.

In some embodiments, at least one of an optical filter or an optical structure may be disposed on top of the color conversion layers CCL. For example, the color filter CF and the lens LS may be disposed on top of each of the color conversion layers CCL. Accordingly, the color purity and light emission rate of the pixels PX may be increased.

The display device 10 according to an embodiment of the disclosure can be applied to various electronic devices. The electronic device according to the one embodiment of the disclosure includes the display device 10 described above, and may further include modules or devices having additional functions in addition to the display device 10.

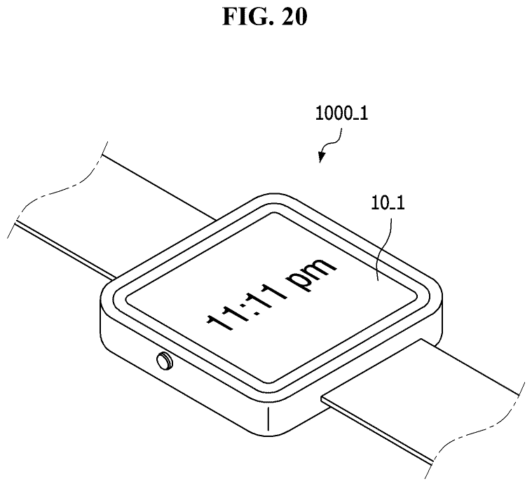

FIG. 20 is a schematic diagram illustrating a smart watch including a display device according to an embodiment.

Referring to FIG. 20, a display device 10_1 according to an embodiment may be applied to a smart watch 1000_1 that is one of the smart devices.

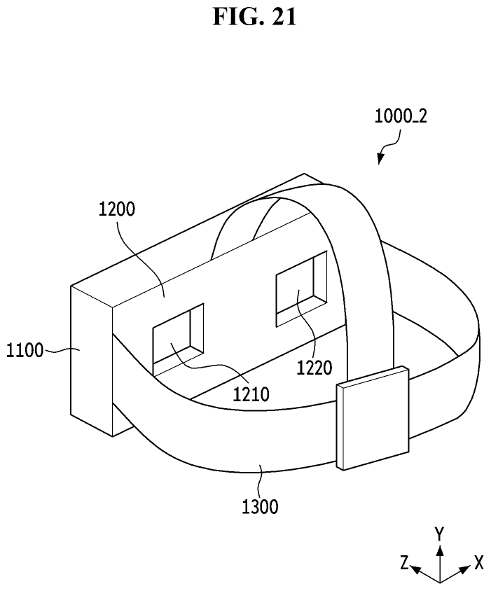

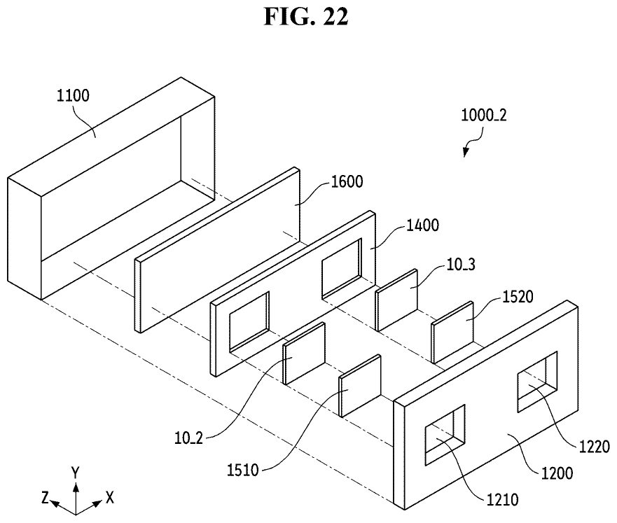

FIGS. 21 and 22 schematically illustrate a head mounted display including a display device according to an embodiment.

Referring to FIGS. 21 and 22, a head mounted display 1000_2 according to an embodiment may be a virtual reality device. The head mounted display 1000_2 includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to the user's left eye, and the second display device 10_3 provides an image to the user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and between the second display device 10_3 and the control circuit board 1600. The middle frame 1400 serves to support and fix the first display device 10_2, the second display device 10_3, and the control circuit board 1600.

The control circuit board 1600 may be disposed between the middle frame 1400 and the display device housing 1100. The control circuit board 1600 may be electrically connected to the first display device 10_2 and the second display device 10_3 through the connector. The control circuit board 1600 may convert an image source inputted from the outside into video data, and transmit the video data to the first display device 10_2 and the second display device 10_3 through the connector.

The control circuit board 1600 may transmit the video data corresponding to a left-eye image optimized for the user's left eye to the first display device 10_2, and may transmit the video data corresponding to a right-eye image optimized for the user's right eye to the second display device 10_3. In another embodiment, the control circuit board 1600 may transmit the same video data to the first display device 10_2 and the second display device 10_3.

The display device housing 1100 may serve to accommodate the first display device 10_2, the second display device 10_3, the middle frame 1400, the first optical member 1510, the second optical member 1520, and the control circuit board 1600. The housing cover 1200 may be disposed to cover an open surface of the display device housing 1100. The housing cover 1200 may include the first eyepiece 1210 at which the user's left eye is located and the second eyepiece 1220 at which the user's right eye is located. FIGS. 21 and 22 illustrate that the first eyepiece 1210 and the second eyepiece 1220 are disposed separately, but the embodiments are not limited thereto. For example, the first eyepiece 1210 and the second eyepiece 1220 may be combined into one piece.

The first eyepiece 1210 may be aligned with the first display device 10_2 and the first optical member 1510, and the second eyepiece 1220 may be aligned with the second display device 10_3 and the second optical member 1520. The user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

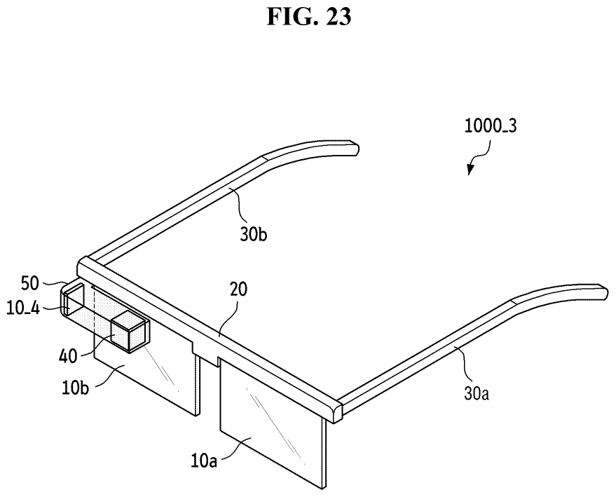

The head mounted band 1300 may serve to secure the display device housing 1100 to the user's head such that the first eyepiece 1210 and the second eyepiece 1220 of the housing cover 1200 remain located on the user's left and right eyes, respectively. In case that the display device housing 1100 is implemented to be lightweight and compact, the head mounted display 1000_2 may be provided with, as shown in FIG. 23, an eyeglass frame instead of the head mounted band 1300.

The head mounted display 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 23 schematically illustrates a head mounted display including a display device according to an embodiment.

Referring to FIG. 23, a head mounted display 1000_3 according to an embodiment may be a glasses-type device. The head mounted display 1000_3 according to an embodiment may include a display device 10_4, a left eye lens 10a, a right eye lens 10b, a support frame 20, temples 30a and 30b, a reflection member 40, and a display device housing 50.

FIG. 23 illustrates that the head mounted display 1000_3 is an eyeglasses-type display device including temples 30a and 30b, but the embodiments are not limited thereto. For example, the head mounted display 1000_3 may be applied in various forms in other electronic devices.

The display device housing 50 may include the display device 10_4 and the reflection member 40 (or an optical path changing member). An image displayed on the display device 10_4 may be reflected by the reflection member 40 and provided to the user's right eye through the right eye lens 10b. As a result, the user may view an augmented reality image, through the right eye, in which a virtual image displayed on the display device 10_4 and a real image seen through the right eye lens 10b are combined. The display device housing 50 may further include an optical member disposed between the display device 10_4 and the reflection member 40. The image displayed on the display device 10_4 may be magnified by the optical member, and may be provided to the user's right eye through the right eye lens 10b after the optical path thereof is changed by the reflection member 40.

Although FIG. 23 illustrates that the display device housing 50 is disposed at the right end of the support frame 20, the embodiment of the disclosure is not limited thereto. For example, the display device housing 50 may be disposed at the left end of the support frame 20, and for example, the image displayed on the display device 10_4 may be reflected by the reflection member 40 and provided to a user's left eye through the left eye lens 10a. As a result, the user may view the image displayed on the display device 10_4 with the left eye. In another embodiment, the display device housing 50 may be disposed at both the left end and the right end of the support frame 20, in which case the user can view the image displayed on the display device 10_4 through both the left eye and the right eye.

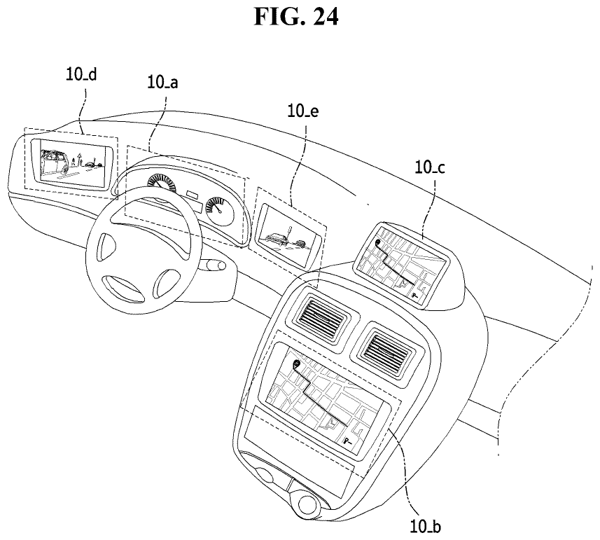

FIG. 24 is a schematic diagram illustrating a dashboard of an automobile and a center fascia including display devices according to an embodiment. FIG. 24 illustrates a vehicle to which display devices 10_a, 10_b, 10_c, 10_d, and 10_e according to an embodiment are applied.

Referring to FIG. 24, the display devices 10_a, 10_b, and 10_c according to an embodiment may be applied to the dashboard of the automobile, the center fascia of the automobile, or the center information display (CID) of the dashboard of the automobile. Further, the display devices 10_d, and 10_e according to an embodiment may be applied to a room mirror display instead of side mirrors of the automobile.

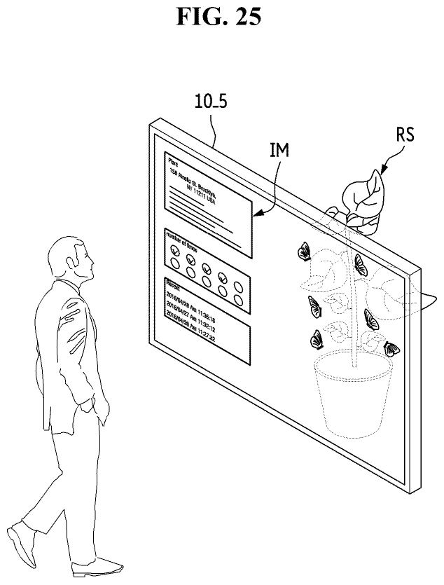

FIG. 25 is a schematic diagram illustrating a transparent display device including a display device according to an embodiment.

Referring to FIG. 25, a display device 10_5 according to an embodiment may be applied to the transparent display device. The transparent display device may display an image IM, and also may transmit light. Thus, a user located on the front side of the transparent display device can view an object RS or a background on the rear side of the transparent display device as well as the image IM displayed on the display device 10_5. In case that the display device 10_5 is applied to the transparent display device, the substrate of the display device 10_5 may include a light transmitting portion capable of transmitting light or may be made of a material capable of transmitting light.

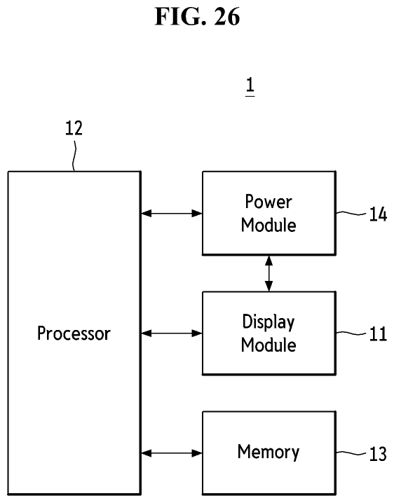

FIG. 26 is a schematic block diagram of an electronic device according to an embodiment of the disclosure.

Referring to FIG. 26, the electronic device 1 according to an embodiment of the disclosure may include a display module 11, a processor 12, a memory 13, and a power module 14.

The display module 11 may include a display panel for displaying an image. For example, the display module 11 may include the display panel DPN according to at least one of the embodiments described above.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. The processor 12 may transmit an image data signal and/or an input control signal stored in the memory 15 to the display module 11. For example, the processor 12 may execute an application stored in the memory 15, the image data signal and/or the input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 1 according to the one embodiment of the disclosure may be included in the display device 10 according to the embodiments of the disclosure. Some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 1 other than the display device 10.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A display device comprising:
a backplane substrate;
a light emitting element layer comprising first electrodes disposed on the backplane substrate, light emitting elements disposed on the first electrodes, and a first oxide layer covering the light emitting elements; and
a light conversion layer disposed on the light emitting element layer, the light conversion layer comprising color conversion layers overlapping the light emitting elements and a second oxide layer covering lower surfaces of the color conversion layers,
wherein the first oxide layer and the second oxide layer are bonded together.

2. The display device of claim 1, wherein the light emitting elements emit ultraviolet or blue light.

3. The display device of claim 2, wherein the color conversion layers comprise a first color conversion layer, a second color conversion layer, and a third color conversion layer converting light emitted from the light emitting elements into light of a first color, light of a second color, and light of a third color, respectively.

4. The display device of claim 3, wherein the light of the first color, the light of the second color and the light of the third color are red light, green light and blue light, respectively.

5. The display device of claim 3, wherein the first color conversion layer, the second color conversion layer, and the third color conversion layer comprise a nitride-based semiconductor material and have a multiple quantum well structure.

6. The display device of claim 5, wherein quantum well layers of each of the first color conversion layer, the second color conversion layer, and the third color conversion layer comprise indium, and
an indium content of the quantum well layers of the first color conversion layer, an indium content of the quantum well layers of the second color conversion layer, and an indium content of the quantum well layers of the third color conversion layer are different from each other.

7. The display device of claim 1, wherein the light emitting element layer comprises:
first reflective layers disposed between the first electrodes and the light emitting elements and covering a lower surface of each of the light emitting elements; and
second reflective layers disposed on the light emitting elements and covering an upper surface of each of the light emitting elements.

8. The display device of claim 7, wherein a reflectivity of the first reflective layers is higher than a reflectivity of the second reflective layers.

9. The display device of claim 7, wherein the first reflective layers comprise a conductive material.

10. The display device of claim 7, wherein each of the second reflective layers comprises first layers and second layers alternately stacked to form a distributed Bragg reflector.

11. The display device of claim 10, wherein a second layer comprising oxide is disposed in an uppermost portion of each of the second reflective layers,
an upper surface of the first oxide layer and upper surfaces of the second reflective layers are coplanar with each other, and
the second oxide layer is bonded to the first oxide layer and the second reflective layers.

12. The display device of claim 7, wherein the first oxide layer covers upper surfaces of the second reflective layers.

13. The display device of claim 7, wherein the light emitting element layer further comprises second electrodes disposed between the light emitting elements and the second reflective layers.

14. The display device of claim 7, wherein a distance between the first reflective layers and the second reflective layers is N, where N is a natural number, times an emission wavelength of the light emitting elements.

15. The display device of claim 1, wherein the light conversion layer further comprises third reflective layers surrounding side surfaces of the color conversion layers.

16. The display device of claim 1, further comprising color filters and a lens disposed on the light conversion layer and covering the color conversion layers.

17. The display device of claim 1, wherein the first oxide layer and the second oxide layer comprise SiO₂ or Al₂O₃.

18. A method of manufacturing a display device, comprising:
forming a display substrate comprising a backplane substrate and a light emitting element layer, and the light emitting element layer comprising a first oxide layer covering light emitting elements;
forming a light conversion layer comprising color conversion layers and a second oxide layer covering the color conversion layers; and
disposing the display substrate and the light conversion layer to face each other, and bonding the first oxide layer and the second oxide layer to bond the display substrate and the light conversion layer.

19. The method of claim 18, wherein the forming of the light conversion layer comprises:
sequentially forming a first color conversion layer, a second color conversion layer, and a third color conversion layer by epitaxial growth on different regions of a manufacturing substrate;
forming a reflective layer on a side surface of each of the first color conversion layer, the second color conversion layer, and the third color conversion layer; and
forming the second oxide layer to cover the first color conversion layer, the second color conversion layer, the third color conversion layer, and the reflective layer.

20. An electronic device comprising:
a display module including a display panel; and
a processor which transmits an image data signal to the display module,
wherein the display panel comprises:
a backplane substrate;
a light emitting element layer comprising first electrodes disposed on the backplane substrate, light emitting elements disposed on the first electrodes, and a first oxide layer covering the light emitting elements; and
a light conversion layer disposed on the light emitting element layer, the light conversion layer comprising color conversion layers overlapping the light emitting elements, and a second oxide layer covering lower surfaces of the color conversion layers, and
the first oxide layer and the second oxide layer are bonded together.
